(19) United States
(12) Patent Application Publication
(10) Pub. No.: US 2026/0182414 A1
(43) Pub. Date: Jun. 25, 2026

(54) TECHNOLOGIES FOR ADVANCED GLASS CORE SUBSTRATES

(71) Applicant: Intel Corporation, Santa Clara, CA (US)

(72) Inventors: Jiun Hann Sir, Gelugor (MY); Eng Huat Goh, Ayer Itam (MY); Telesphor Kamgaing, Chandler, AZ (US); Chan Kim Lee, Penang (MY)

(73) Assignee: Intel Corporation, Santa Clara, CA (US)

(21) Appl. No.: 19/000,837

(22) Filed: Dec. 24, 2024

(51) Int. Cl. H01L 23/538; H01L 23/15; H01L 23/34; H01L 25/18; H10D 1/68

(52) U.S. Cl. CPC H10W 70/65; H10W 40/00; H10W 70/611; H10W 90/00; H10D 1/68; H10W 70/692

(57) ABSTRACT

Technologies for advanced glass-core substrates are disclosed. In one embodiment, an integrated circuit component has a substrate with a glass core. One or more dies are mounted on one side of the glass core, and one or more build-up layers are disposed on the other side of the glass core. The asymmetry in build-up layers allows for various advantages in various embodiments. In one embodiment, the coefficient of thermal expansion (CTE) of the glass core matches that of the dies, reducing stress between the glass core and the dies and increasing attach yield. In some embodiments, the glass core has a gradient of CTE, allowing the CTE to be matched to both the dies on top and the build-up layers on the bottom. In some embodiment, a thin-film bridge die may be positioned in the glass core.

### BACKGROUND

Glass cores for integrated circuit components, circuit boards, and other electronic components are becoming more common. Build-up layers can be deposited on the glass core in order to provide redistribution layers to connect the various dies of the integrated circuit component. However, the coefficient of thermal expansion (CTE) of the glass core, the build-up layers, and the dies may be mismatched, causing stress when subject to thermal cycling. In some cases, the stress can cause cracks in the glass cores or other components and/or cause poor or broken connections between components.

### BRIEF DESCRIPTION OF THE DRAWINGS

FIG. 1 is an isometric view of one embodiment of a system with an integrated circuit component with a substrate with a glass core.

FIG. 2 is a cross-sectional view of one embodiment of the system of FIG. 1.

FIG. 3 is a cross-sectional view of one embodiment of the integrated circuit component of FIG. 1.

FIG. 4 is a cross-sectional view of one embodiment of the integrated circuit component of FIG. 1.

FIG. 5 is a cross-sectional view of one embodiment of the integrated circuit component of FIG. 1.

FIG. 6 is a flowchart of one embodiment of a method of creating one embodiment of the integrated circuit component of FIG. 1.

FIG. 7 is a cross-sectional view of one embodiment of a system at one stage of the flowchart of FIG. 6.

FIG. 8 is a cross-sectional view of one embodiment of a system at one stage of the flowchart of FIG. 6.

FIG. 9 is a cross-sectional view of one embodiment of a system at one stage of the flowchart of FIG. 6.

FIG. 10 is a cross-sectional view of one embodiment of a system at one stage of the flowchart of FIG. 6.

FIG. 11 is a cross-sectional view of one embodiment of a system at one stage of the flowchart of FIG. 6.

FIG. 12 is a cross-sectional view of one embodiment of a system at one stage of the flowchart of FIG. 6.

FIG. 13 is a cross-sectional view of one embodiment of a system at one stage of the flowchart of FIG. 6.

FIG. 14 is a cross-sectional view of one embodiment of a system at one stage of the flowchart of FIG. 6.

FIG. 15 is a cross-sectional view of one embodiment of a system at one stage of the flowchart of FIG. 6.

FIG. 16 is a cross-sectional view of one embodiment of a system at one stage of the flowchart of FIG. 6.

FIG. 17 is a cross-sectional view of one embodiment of a system at one stage of the flowchart of FIG. 6.

FIG. 18 is a cross-sectional view of one embodiment of the integrated circuit component of FIG. 1 with a glass core with a gradient of coefficients of thermal expansion (CTEs).

FIG. 19 is a flowchart of one embodiment of a method of creating one embodiment of the integrated circuit component of FIG. 18.

FIG. 20 is a cross-sectional view of one embodiment of a system at one stage of the flowchart of FIG. 19.

FIG. 21 is a cross-sectional view of one embodiment of a system at one stage of the flowchart of FIG. 19.

FIG. 22 is a cross-sectional view of one embodiment of a system at one stage of the flowchart of FIG. 19.

FIG. 23 is a cross-sectional view of one embodiment of a system at one stage of the flowchart of FIG. 19.

FIG. 24 is a cross-sectional view of one embodiment of a system at one stage of the flowchart of FIG. 19.

FIG. 25 is a cross-sectional view of one embodiment of a system at one stage of the flowchart of FIG. 19.

FIG. 26 is a cross-sectional view of one embodiment of a system at one stage of the flowchart of FIG. 19.

FIG. 27 is a cross-sectional view of one embodiment of a system at one stage of the flowchart of FIG. 19.

FIG. 28 is a cross-sectional view of one embodiment of a system at one stage of the flowchart of FIG. 19.

FIG. 29 is a cross-sectional view of one embodiment of the integrated circuit component of FIG. 1 with a glass core with a thin-film interconnect bridge.

FIG. 30 is a flowchart of one embodiment of a method of creating one embodiment of the integrated circuit component of FIG. 29.

FIG. 31 is a cross-sectional view of one embodiment of a system at one stage of the flowchart of FIG. 30.

FIG. 32 is a cross-sectional view of one embodiment of a system at one stage of the flowchart of FIG. 30.

FIG. 33 is a cross-sectional view of one embodiment of a system at one stage of the flowchart of FIG. 30.

FIG. 34 is a cross-sectional view of one embodiment of a system at one stage of the flowchart of FIG. 30.

FIG. 35 is a cross-sectional view of one embodiment of a system at one stage of the flowchart of FIG. 30.

FIG. 36 is a cross-sectional view of one embodiment of a system at one stage of the flowchart of FIG. 30.

FIG. 37 is a cross-sectional view of one embodiment of a system at one stage of the flowchart of FIG. 30.

FIG. 38 is a cross-sectional view of one embodiment of a system at one stage of the flowchart of FIG. 30.

FIG. 39 is a cross-sectional view of one embodiment of a system at one stage of the flowchart of FIG. 30.

FIG. 40 is a cross-sectional view of one embodiment of a system at one stage of the flowchart of FIG. 30.

FIG. 41 is a cross-sectional view of one embodiment of a system at one stage of the flowchart of FIG. 30.

FIG. 42 is a cross-sectional view of one embodiment of a system at one stage of the flowchart of FIG. 30.

FIG. 43 is a cross-sectional view of one embodiment of a system at one stage of the flowchart of FIG. 30.

FIG. 44 is a cross-sectional view of one embodiment of a system at one stage of the flowchart of FIG. 30.

FIG. 45 is a cross-sectional view of one embodiment of a system at one stage of the flowchart of FIG. 30.

FIG. 46 is a cross-sectional view of one embodiment of a system at one stage of the flowchart of FIG. 30.

FIG. 47 is a cross-sectional view of one embodiment of a system at one stage of the flowchart of FIG. 30.

FIG. 48 is a top view of a wafer and dies that may be included in a microelectronic assembly, in accordance with any of the embodiments disclosed herein.

FIG. 49 is a cross-sectional side view of an integrated circuit device that may be included in a microelectronic assembly, in accordance with any of the embodiments disclosed herein.

FIGS. 50A-50D are perspective views of example planar, gate-all-around, and stacked gate-all-around transistors.

FIG. 51 is a cross-sectional side view of an integrated circuit device assembly that may include a microelectronic assembly, in accordance with any of the embodiments disclosed herein.

FIG. 52 is a block diagram of an example electrical device that may include a microelectronic assembly, in accordance with any of the embodiments disclosed herein.

### DETAILED DESCRIPTION

In various embodiments disclosed herein, an integrated circuit component has a substrate with a glass core. One or more dies are positioned on the top surface of the glass core, and one or more build-up layers are on the bottom surface of the glass core. In an illustrative embodiment, the coefficient of thermal expansion of the glass core matches that of the dies, preventing thermally-induced stress between the glass core and the dies. In some embodiments, the glass core has a gradient of a coefficient of thermal expansion. In such an embodiment, the coefficient of thermal expansion of the glass core may match that of the dies on the top side of the glass core and match that of the build-up layers on the bottom side of the glass core, mitigating stress at both the top side and the bottom side of the glass core.

In some embodiments, a bridge interconnect may be embedded in the glass core at the top side. The bridge interconnect can provide short, high-bandwidth connections between neighboring dies. In some embodiments, the bridge interconnect may be a thin-film bridge interconnect, as described in more detail below.

The approaches described herein can, in various embodiments, provide several advantages. The approaches are flexible, and various features can be combined in different embodiments, leading to a variety of possible products using shared technologies. The approaches described herein both offer high performance and allow for manufacturing at scale. The techniques can lead to high chip attach yield, high surface mount (SMT) yield, and better component-level reliability. The techniques also allow for reduced complexity and densely-packaged dies.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, a die may be considered to be adjacent a substrate if there are no layers or components between the die and the substrate, although there can be pads, solder balls, etc., between the substrate and the die, with the die and the substrate still considered to be adjacent. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc., means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

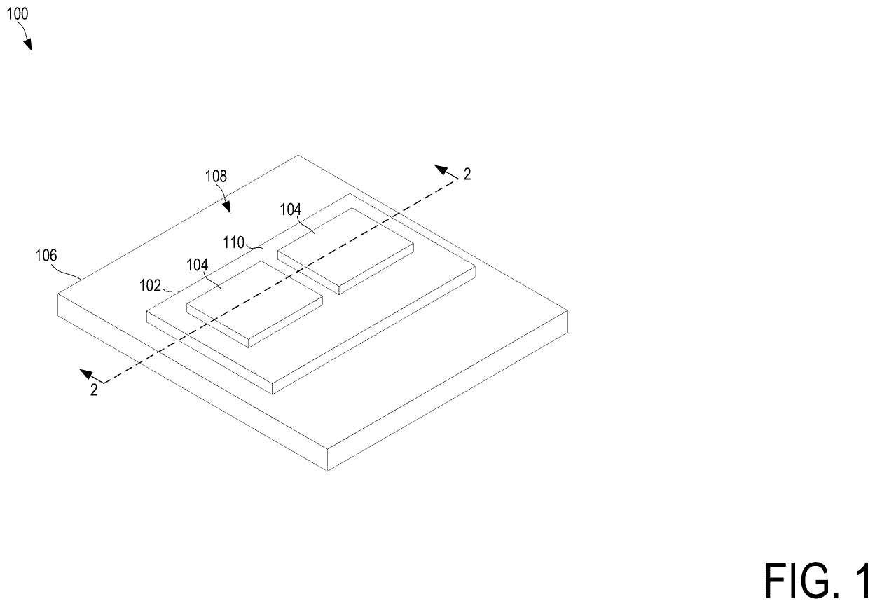

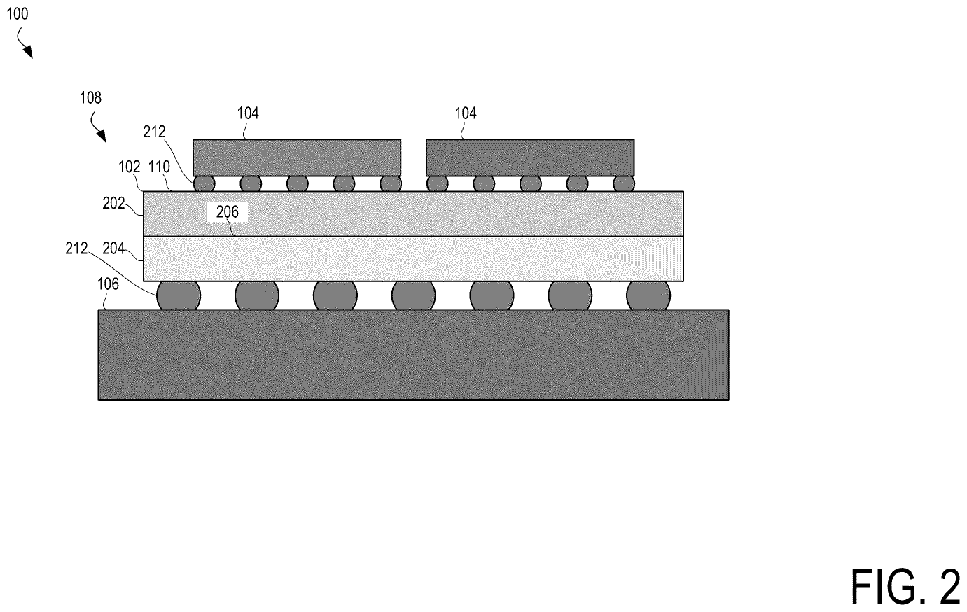

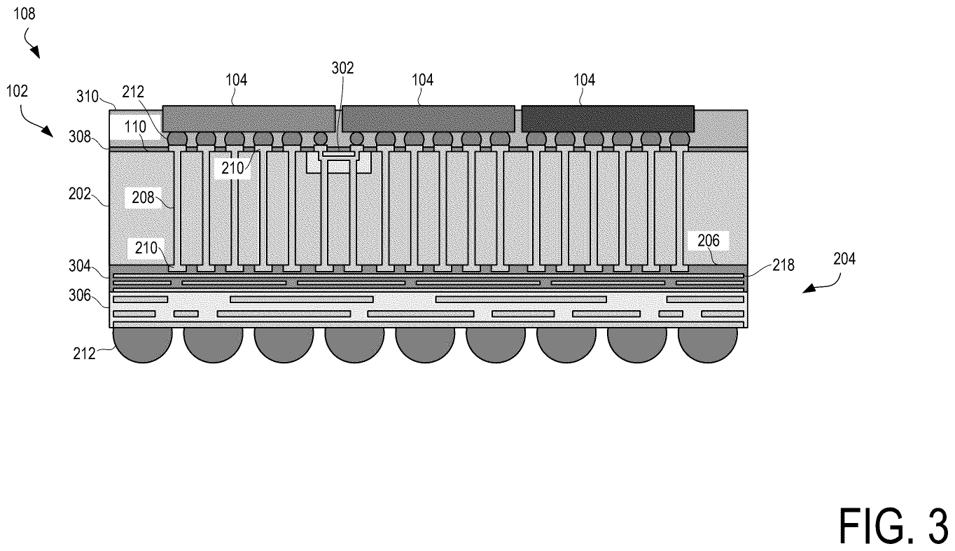

Referring now to FIGS. 1-5, in one embodiment, a system 100 includes an integrated circuit component 108 mounted on a circuit board 106. The integrated circuit component 108 includes a substrate 102 on which one or more dies 104 are mounted. FIG. 1 shows an isometric view of the integrated circuit component 108 and circuit board 106, and FIG. 2 shows a cross-sectional view of the integrated circuit component 108 and circuit board 106. FIGS. 3-5 show a cross-sectional view of various embodiments of the integrated circuit component 108. As shown in FIG. 1, a die 104 such as a processor die 104 may be disposed on the top surface 110 or top side of the substrate 102. In an illustrative embodiment, additional components, such as other semiconductor dies (such as memory dies, other processor dies, etc.), are disposed on the top surface 110 of the substrate 102 as well.

It should be appreciated that, as used herein, the “top side,” “bottom side,” etc., is an arbitrary designation used for clarity and does not denote a particular required orientation for manufacture or use. Although the illustrative embodiment described has the dies 104 placed on the “top” side of the substrate 102, in some embodiments, those components may be placed on the “bottom” side of the substrate 102.

The substrate 102 includes a glass core 202 and build-up layers 204. In an illustrative embodiment, the glass core 202 has a coefficient of thermal expansion (CTE) that is similar to or the same as that of the dies 104. For example, the dies 104 may have a CTE of, e.g., 3 parts per million (ppm) per degree Celsius, and the glass core 202 may have a CTE of, e.g., 2-4 ppm/° C. In general, the glass core 202 may have a CTE that is, e.g., within 0-5 ppm/° C. and/or within 0-50% of the CTE of the dies 104. In some embodiments, the dies 104 have silicon substrates and have a CTE corresponding to that of silicon.

It should be noted that, in an illustrative embodiment, there is an asymmetry in the build-up layers 204 in that there are not build-up layers on the top surface 110 of the glass core 202, and the dies 104 are mounted directly on the glass core 202. As such, build-up layers that could potentially have a different CTE do not disrupt the matching CTE between the glass core 202 and the dies 104. As such, there is little to no thermal stress between the dies 104 and the glass core 202, even after repeated thermal cycling and during high-temperature processing steps.

In an illustrative embodiment, the build-up layers 204 provide interconnects between the various dies 104 and between the dies 104 and other components, such as other components connected to the circuit board 106. However, in some cases, shorter path lengths that do not extend through the glass core 202 may be preferred. In some embodiments, a bridge die 302 may be disposed at the top surface 110 of the glass core 202. The bridge die 302 may provide high-density, high-bandwidth, low-latency connections between neighboring dies 104.

In an illustrative embodiment, the substrate 102 is a multi-layer substrate 102 with one or more build-up layers 204 on the bottom side 206 of the glass core 202. The build-up layers 204 may have any suitable number of layers, such as 1-10 layers. In other embodiments, the substrate 102 may be a single-layer substrate 102. In an illustrative embodiment, the glass core 202 is an inorganic core, such as a glass core. The glass core may be silicon oxide glass. In other embodiments, the glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight. In other embodiments, the glass core 202 may be an organic core, such as a fiberglass board made of glass fibers and a resin, such as FR-4.

The thickness of the substrate 102 may be any suitable thickness, such as 100 micrometers to 5 millimeters. The thickness of the glass core 202 may be any suitable thickness, such as 50 micrometers to 2 millimeters. The substrate 102 can have any suitable length and width, such as 1-500 millimeters. Although shown as a rectangle, it should be appreciated that the substrate 102 may be any suitable shape and may have protrusions, cutouts, etc., in order to accommodate, fit, or touch other components of a device. In the illustrative embodiment, the substrate 102 is planar. In other embodiments, the substrate 102 may be non-planar.

In an illustrative embodiment, the die 104 is a processor die, and other dies may be memory dies communicatively coupled to the processor die 104. In other embodiments, the die 104 and/or the dies may be any suitable die, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104 may be connected to contact pads 210 or vias 208 on the substrate 102 through conductive contacts 212, such as solder balls or bumps. In some embodiments, the dies 104 may be referred to as chiplets. Underfill 310 may surround the dies 104 and the conductive contacts 212.

The dies 104 may have any suitable hybrid bump pitch, with a small bump pitch, such as 10-55 micrometers, or a large bump pitch, such as 90 micrometers or more. In an illustrative embodiment, the die-to-die spacing (i.e., the amount of space between neighboring dies) can be as low as 40 μm. More generally, the die-to-die spacing may be, e.g., 40-500 micrometers. It should be appreciated that the reduced mismatch in CTE between the dies 104 and the glass core 202 can allow for small die-to-die spacing while maintaining a high yield.

Holes or cavities are defined in the glass core 202 that extend from the top surface 110 of the glass core 202 to the bottom side 206 of the glass core 202, as shown in FIGS. 3-5. Vias 208 are disposed in the holes. Via pads 210 are formed at one or both ends of the via 208. The via pads 210 may also be referred to as caps or via caps. The vias 208 in the core 202 may transport power and/or data signals through the glass core 202. In an illustrative embodiment, the vias 208 are made of copper. In other embodiments, the vias 208 may be made of any suitable conductive material, such as tungsten, polysilicon, etc. The core 202 may have any suitable number of vias 208 extending through it, such as 1-10,000 vias 208. The vias 208 may have any suitable diameter, such as 10-500 micrometers. The vias 208 may be connected to other traces 218, vias, etc., on the build-up layers 204 to connect to various components on the top surface or bottom surface of the substrate 102. The traces 218 and vias may be made of any suitable conductive material, such as copper or aluminum.

In an illustrative embodiment, the bridge die 302 provide high-density, high-bandwidth, low-latency connections between neighboring dies 104. The minimum line and spacing for traces in the bridge die 302 may be 0.4-0.5 micrometers, with a trace pitch of 0.8-1 micrometers. In an illustrative embodiment, the bridge die 302 has a silicon substrate. The silicon substrate may have a thickness of, e.g., 200-400 micrometers. In some embodiments, some or all of the silicon substrate of the bridge die 302 may be removed, as discussed in more detail below.

In an illustrative embodiment, the build-up layers 204 may include a fine redistribution layer 304 with traces with relatively fine lines and spacing as well as a coarse distribution layer 306 with traces with relatively coarse lines and spacing. In an illustrative embodiment, the fine redistribution layer 304 has a minimum line and spacing for traces as low as, e.g., 1-2 micrometers, with a trace pitch of 2-4 micrometers. In the illustrative embodiment, the coarse redistribution layer 306 has a minimum line and spacing for traces as low as, e.g., 9-15 micrometers, with a trace pitch of 18-30 micrometers. The height of each layer of the fine redistribution layer 304 may be, e.g., 3-10 micrometers, and the height of each layer of the coarse redistribution layer 306 may be, e.g., 5-15 micrometers. In some embodiments, the fine redistribution layer 304 may perform a similar functionality as a redistribution layer in an interposer, and the coarse redistribution layer 306 may perform a similar functionality as a redistribution layer in a substrate. The build-up layers 204 may be made of any suitable material or materials, such as any suitable dielectric that can support the traces 218, vias, etc. In some embodiments, the dielectric for the fine redistribution layer 304 is made of polyimide, and the dielectric for the coarse redistribution layer 306 is made Ajinomoto build-up film (ABF).

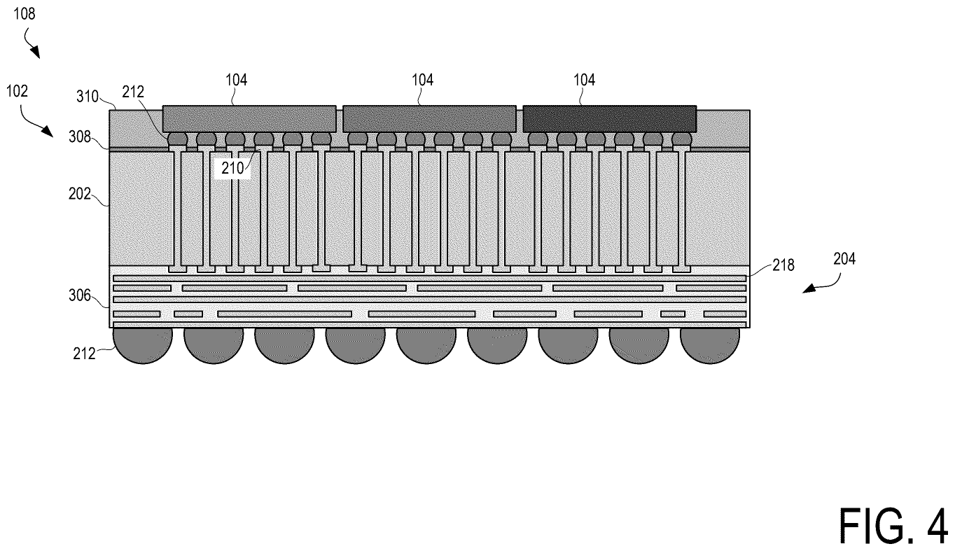

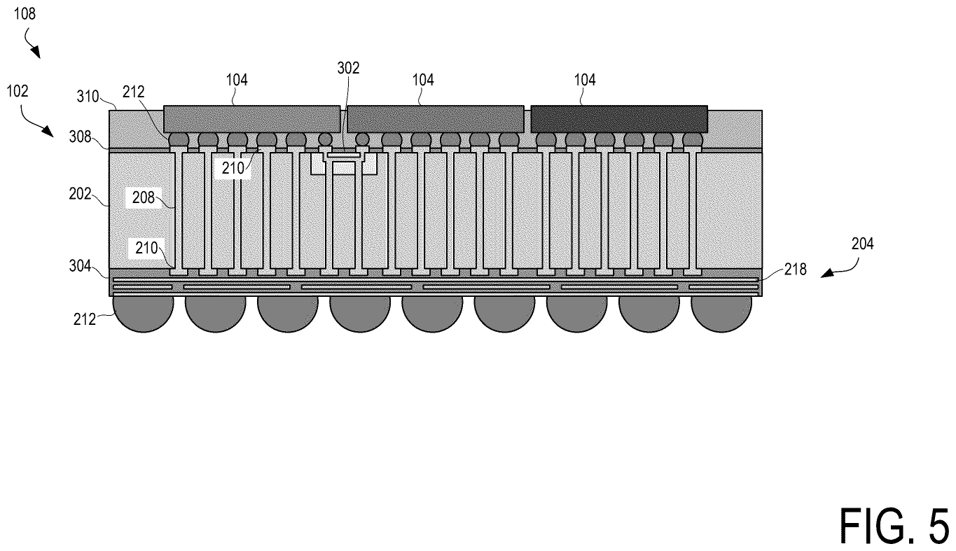

The illustrative embodiment shown in FIG. 3 has a bridge die 302, a fine redistribution layer 304, and a coarse redistribution layer 306. In other embodiments, different combinations may be possible. For example, in one embodiment, a bridge die 302 may not be used, and only a coarse redistribution layer 306 is used, as shown in FIG. 4. In another embodiment, a bridge die 302 is be used, and only a fine redistribution layer 304 is used, as shown in FIG. 5. The different embodiments allow for relatively small, low-cost variations that can be used for a variety of different applications and markets.

The approach described above offers several advantages. The approach can offer similar performance as an organic substrate combined with an organic or silicon interposer, without the additional component of an interposer. Due to the low stress and low CTE mismatch, the yield rate for attaching dies 104 to the glass core 202 is high. The glass core 202 avoids the reticle size limiting complexity and lossy through-silicon vias of a silicon interposer. The glass core 202 also avoids warpage-induced assembly yield loss for an organic interposer, especially for this dies. The bridge die 302 in the glass core 202 provides connectivity without a Z height or lateral routing block penalty. In contrast, an organic interposer with a bridge may lead to longer channels due to the stack via, and a bridge die in a through-mold via may lead to a higher Z height. A bridge die in a build-up layer may block lateral routing for input/output and/or power signals. The flat surface of the glass core 202 is capable of supporting a fine redistribution layer 304, similar to an organic interposer, offering more routing options for die-to-die interconnect, such as a UCIE-A interconnect with 32 Gbps per lane and input/output breakouts with a smaller footprint. Additionally, a glass core 202 is compatible with optical interconnects, such as by integrating waveguides, mirrors, lenses, or other optical components into the glass core.

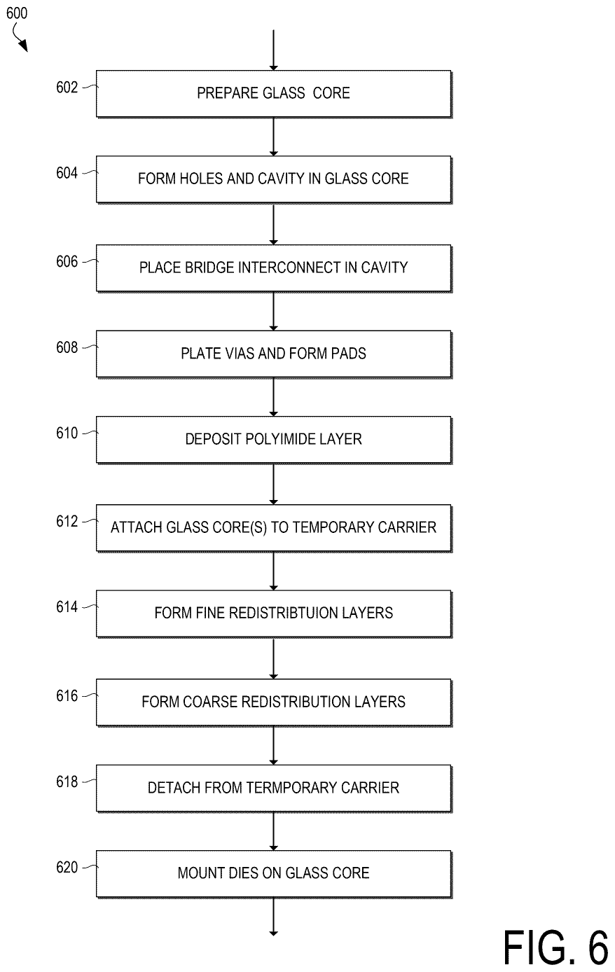

Referring now to FIG. 6, in one embodiment, a flowchart for a method 600 for creating the integrated circuit component 108 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, cause the machine to perform some or all of the steps of the method 600. The method 600 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 600 is merely one embodiment of a method to create one embodiment of a system, and other methods may be used to create any suitable embodiment of the system. In some embodiments, steps of the method 600 may be performed in a different order than that shown in the flowchart.

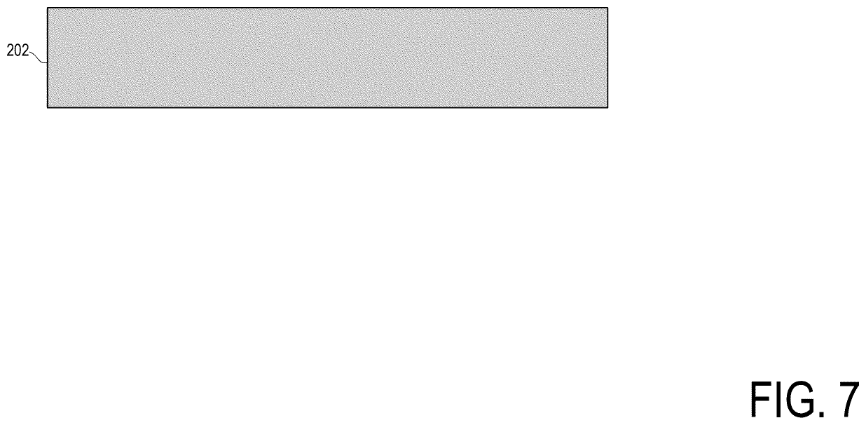

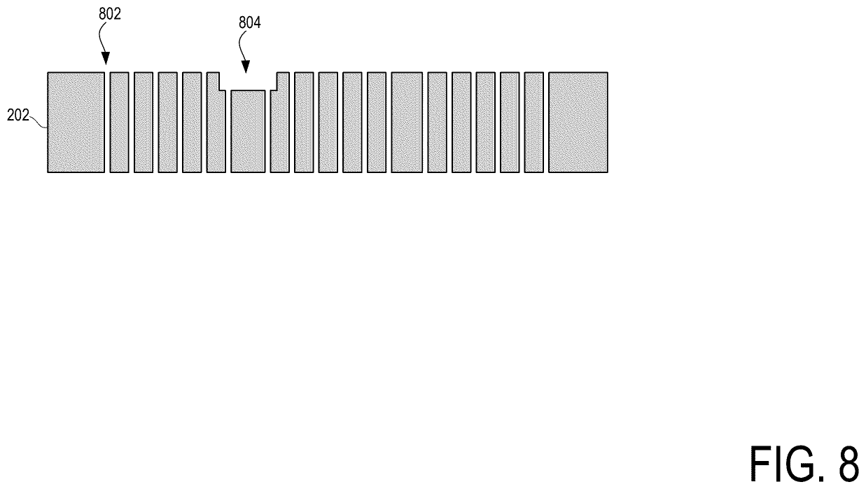

The method 600 begins in block 602, in which a glass core 202 is prepared, such as by dicing, polishing, etc., as shown in FIG. 7. In block 604, holes 802 and/or cavities 804 are formed in the substrate core, as shown in FIG. 8. In an illustrative embodiment, laser-induced deep etching (LIDE) is used to form the holes 802 and/or the cavity 804. In other embodiments, other techniques may be used, such as laser drilling, mechanical drilling, etching, etc.

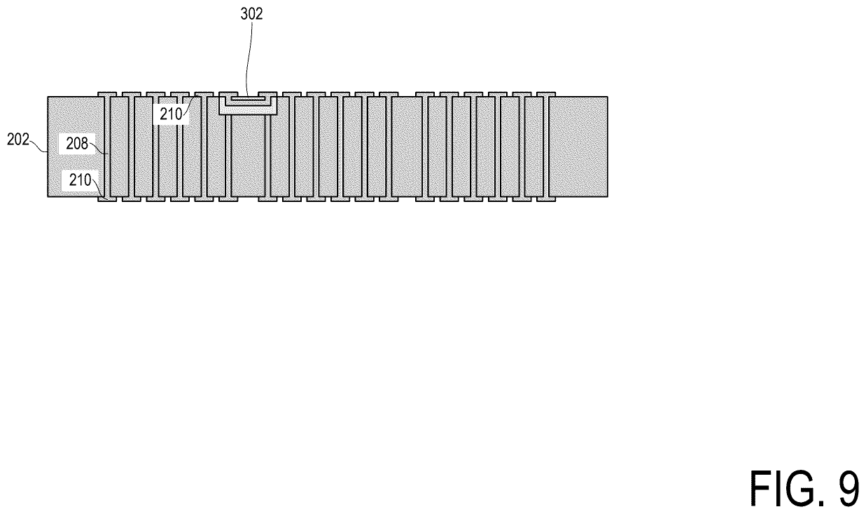

In block 606, a bridge die 302 is placed in the cavity 804. In block 608, vias 208, pads 210, and other traces are formed, as shown in FIG. 9. In an illustrative embodiment, the vias 208 and pads 210 may be formed by depositing a seed layer using electroless plating, patterning a photoresist, electroplating the seed layer, and then removing the photoresist and the remaining seed layer.

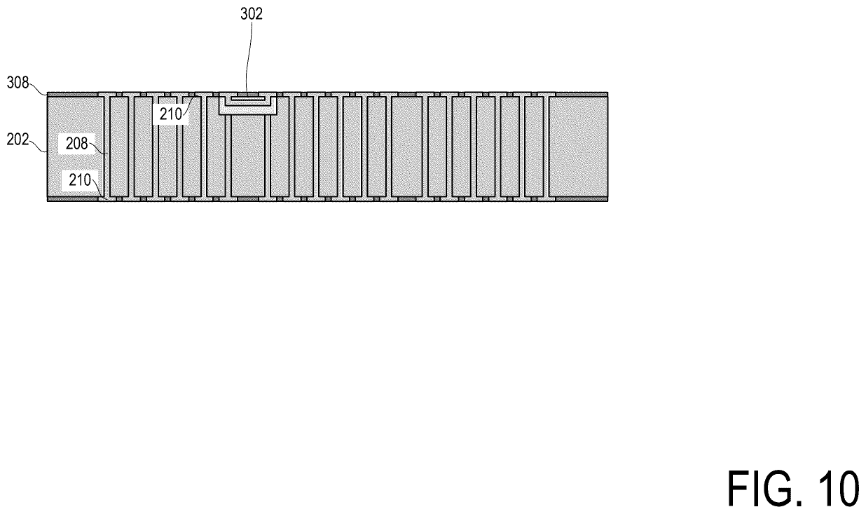

In block 610, a polyimide layer 308 is deposited over the pads 210, creating a dielectric barrier between the pads 210 and other traces and higher layers of traces, as shown in FIG. 10.

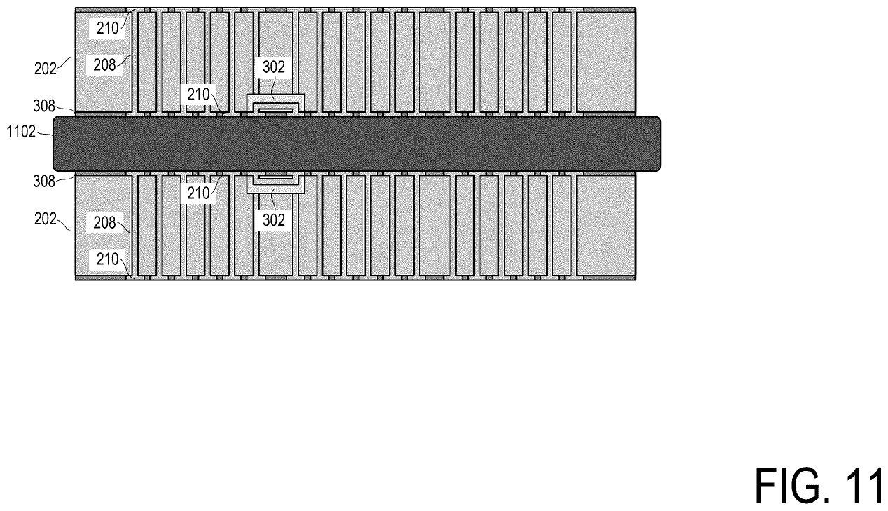

In block 612, the glass core 202 is attached to a temporary carrier 1102. In an illustrative embodiment, another glass core 202 is mounted on the other side of the temporary carrier 1102, as shown in FIG. 11. Such an approach allows for forming build-up layers on two glass cores 202 at the same time. In some embodiments, a glass core 202 may be mounted only on one side of the carrier 1102. The temporary carrier 1102 may be any suitable material, such as glass, silicon, quartz, a ceramic, etc.

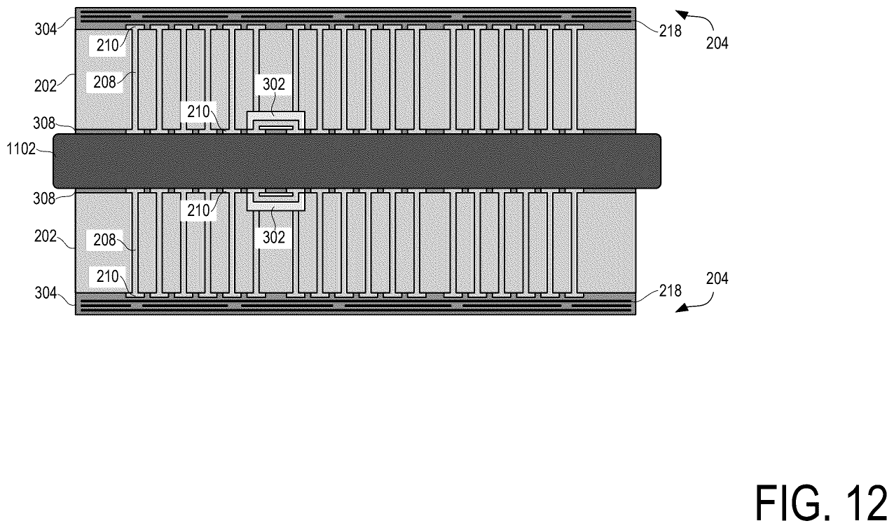

In block 614, one or more fine redistribution layers 304 are formed on the glass core(s) 202, as shown in FIG. 12. Any suitable process may be used, such as embedded traces in polyimide or a semi-additive process on polyimide. The fine redistribution layers 304 may include traces, vias, pads, etc.

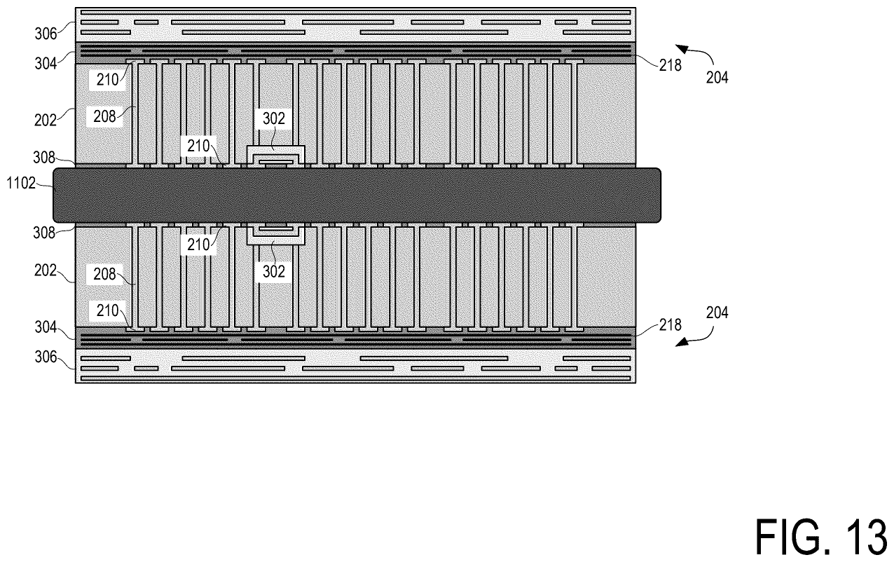

In block 616, one or more coarse redistribution layers 306 are formed on the fine redistribution layers 304, as shown in FIG. 13. Any suitable process may be used, such as a semi-additive process on polyimide or using Ajinomoto build-up film (ABF).

In some embodiments, the CTE of the build-up layers 204 may not match that of the glass core 202. As a result, in-process warpage is possible. In some embodiments, the warpage can be reduced or minimized using a glass core 202 or carrier 1102 with a higher Young's modulus. In general, warping is inversely proportional to the Young's modulus. The glass core 202 and/or carrier 1102 may have any suitable Young's modulus, such as 60-140 GPa.

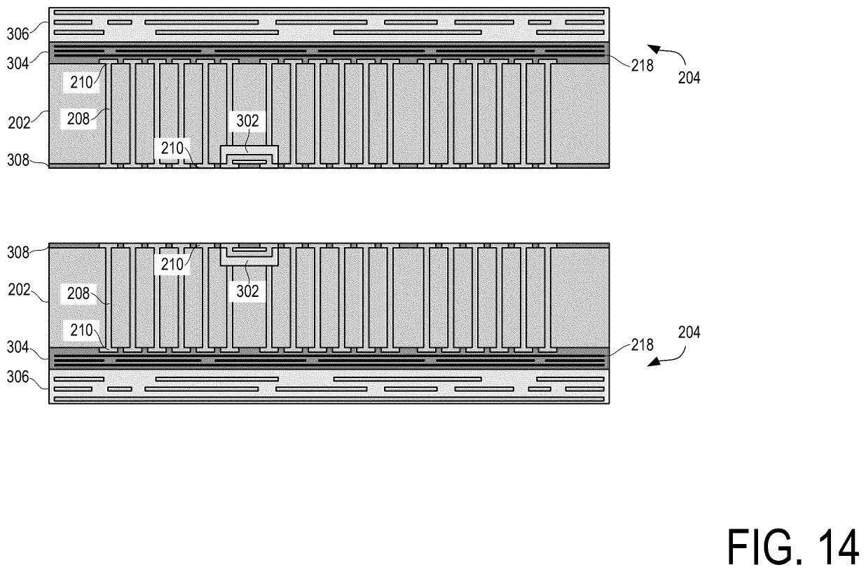

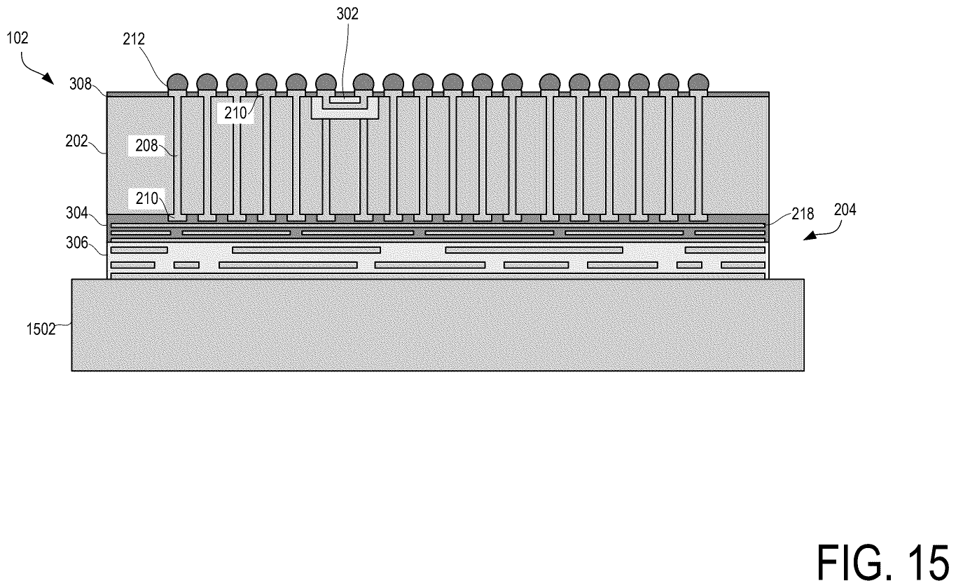

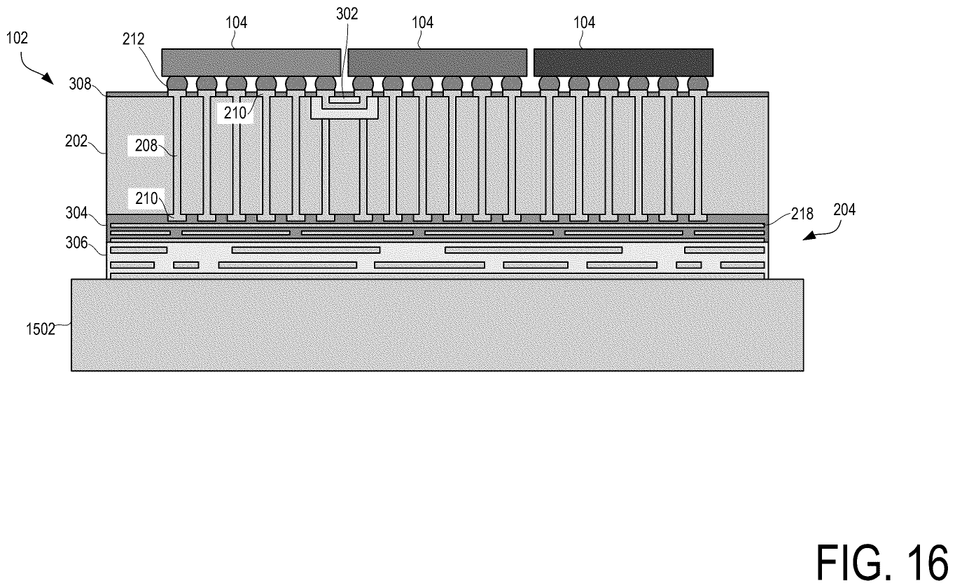

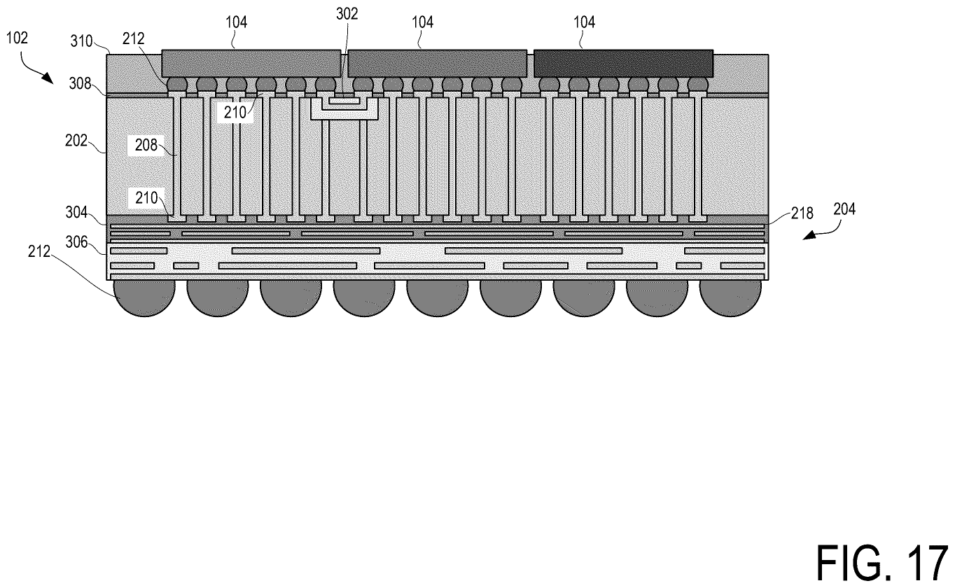

In block 618, the glass core(s) 202 are detached from the temporary carrier, as shown in FIG. 14. In block 620, dies 104 are mounted on the glass core 202. In an illustrative embodiment, as shown in FIG. 15, the glass core 202 may be mounted on a glass carrier 1502 while the dies 104 are attached, which may reduce or minimize potential warpage during the die attach process. The dies 104 may be attached using any suitable process, such as mass reflow, thermos-compression bonding, etc., as shown in FIG. 16. Underfill 310 may be added, which may be a molded underfill. Conductive contacts 212, such as solder balls, are then added, as shown in FIG. 17.

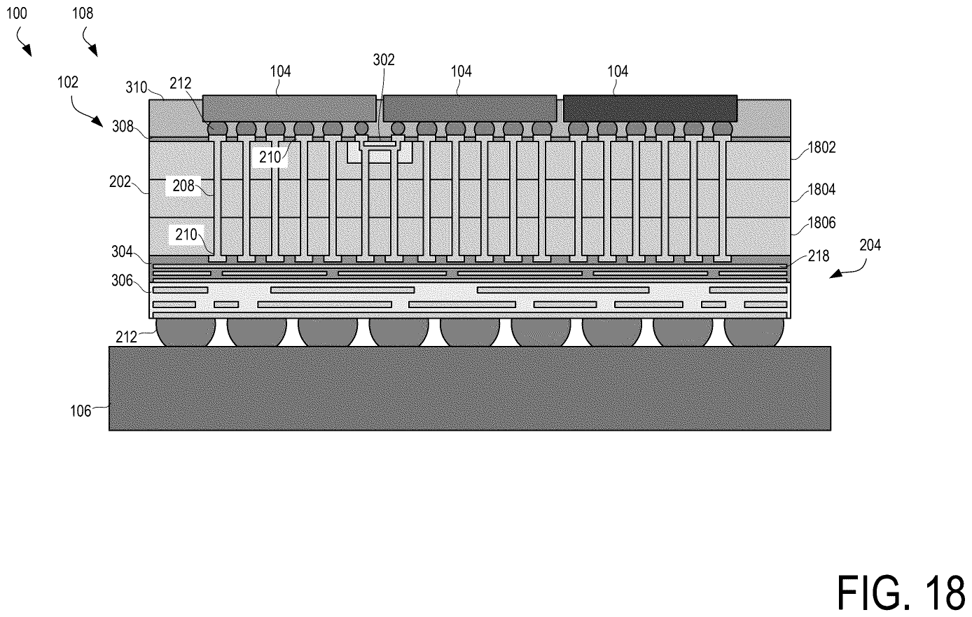

Referring now to FIG. 18, in one embodiment, an integrated circuit component 108 includes a glass core 202 that has a gradient in its CTE. In an illustrative embodiment, the glass core 202 has a first sub-core 1802 with a first CTE, a second sub-core 1804 with a second CTE, and a third sub-core 1806 with a third CTE. In an illustrative embodiment, the CTE of the first sub-core 1802 is similar to that of the dies 104, the CTE of the third sub-core 1806 is similar to that of the build-up layers 204, and the CTE of the second sub-core 1804 is between that of the first sub-core 1802 and the third sub-core 1806.

The various components of the system 100 may have any suitable CTE. For example, the dies 104 may have a CTE of, e.g., 2-4 ppm/° C., the first sub-core 1802 may have a CTE of, e.g., 2-4 ppm/° C., the second sub-core 1804 may have a CTE of, e.g., 5-10 ppm/° C., the third sub-core 1806 may have a CTE of, e.g., 12-17 ppm/° C., and the build-up layers 204 may have a CTE of, e.g., 12-17 ppm/° C. In some embodiments, the circuit board 106 may have a CTE that is higher than that of the build-up layers 204, such as 18-22 ppm/° C. In general, the first sub-core 1802 may have a CTE that is, e.g., within 0-5 ppm/° C. and/or within 0-50% of the CTE of the dies 104, the third sub-core 1806 may have a CTE that is, e.g., within 0-5 ppm/° C. and/or within 0-50% of the CTE of the build-up layers 204 and the second sub-core 1804 may have a CTE that is anywhere between that of the first sub-core 1802 and the third sub-core 1806. In some embodiments, the dies 104 have silicon substrates and have a CTE corresponding to that of silicon. In the illustrative embodiment, the glass core 202 has three sub-cores 1802, 1804, 1806. In other embodiments, there may be more or fewer sub-cores, such as 2-10. In an illustrative embodiment, the interface between two sub-cores 1802 may be identified by having a higher concentration of oxygen. In some embodiments, there may not be any sub-cores in the glass core 202, but the glass core 202 may have a gradient of CTE due to doping of the glass core 202, such as ion implantation or dopant diffusion.

The CTE of the sub-cores 1802, 1804, 1806 may be tuned in any suitable manner, such as by changing the concentration of certain atoms, ions, or dopants in the glass (e.g., the amount of silicon, aluminum, sodium, potassium, boron, titanium, zirconium, metal oxides, etc.), changing the type of glass, adding or removing particles from the glass (such as ceramics), by changing the crystallization of the glass, by heat treatment of the glass, etc., and/or any suitable combinations thereof.

Using a glass core 202 with a gradient in its CTE offers several advantages, in various embodiments. As discussed above, the first sub-core 1802 matching the CTE of the dies 104 allows for better die attach yield, similar to a silicon interposer, and better first-level interconnect reliability. The third sub-core 1806 matching the CTE of the build-up layers 204 can lead to better surface mount (SMT) yield, similar to an organic substrate, and better second-level interconnect reliability. The second sub-core 1804 can mitigate stress in the glass core 202, offering better component level reliability.

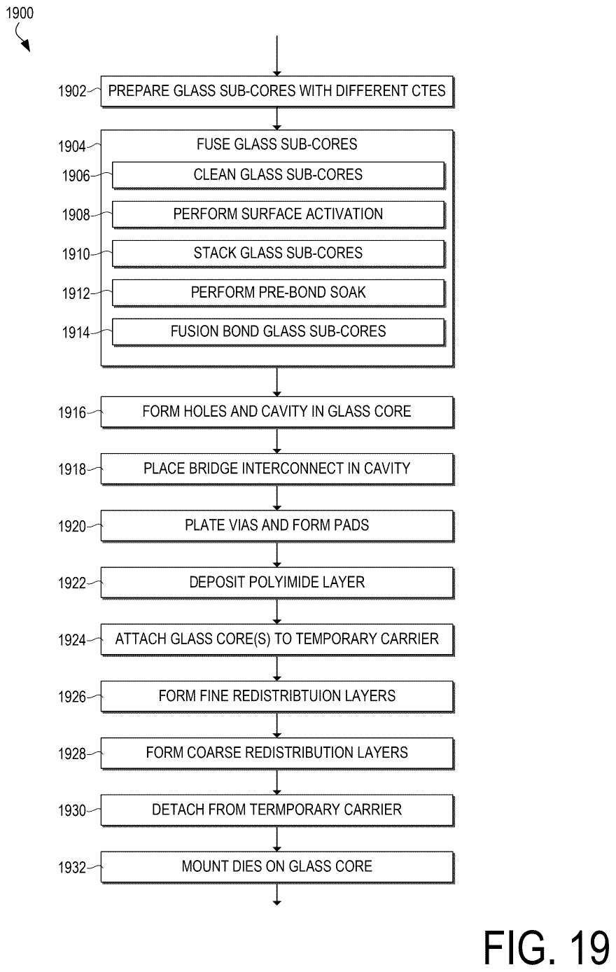

Referring now to FIG. 19, in one embodiment, a flowchart for a method 1900 for creating the integrated circuit component 108 is shown. The method 1900 may be executed by a technician and/or by one or more automated machines. In some embodiments, one or more machines may be programmed to do some or all of the steps of the method 1900. Such a machine may include, e.g., a memory, a processor, data storage, etc. The memory and/or data storage may store instructions that, when executed by the machine, cause the machine to perform some or all of the steps of the method 1900. The method 1900 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 1900 is merely one embodiment of a method to create one embodiment of a system, and other methods may be used to create any suitable embodiment of the system. In some embodiments, steps of the method 1900 may be performed in a different order than that shown in the flowchart.

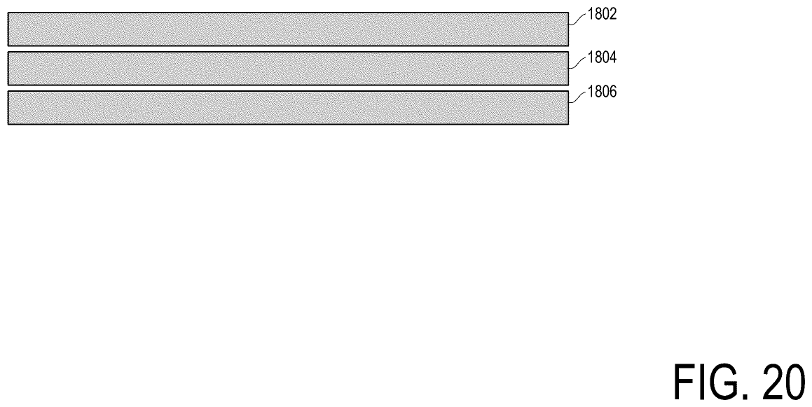

The method 1900 begins in block 1902, in which glass sub-cores 1802, 1804, 1806 with different CTEs are prepared, such as by dicing, polishing, etc., as shown in FIG. 20.

In block 1904, the glass sub-cores 1802, 1804, 1806 are fused together. One possible embodiment for fusing the glass sub-cores 1802, 1804, 1806 is described below in detail. It should be appreciated that this is merely one possible embodiment, and other embodiments are envisioned as well.

In block 1906, the glass sub-cores 1802, 1804, 1806 are cleaned, such as by using a piranha solution (a mixture of sulfuric acid and hydrogen peroxide) or other solvents. In block 1908, surface activation is performed, such as by using a two-step plasma process using oxygen and nitrogen.

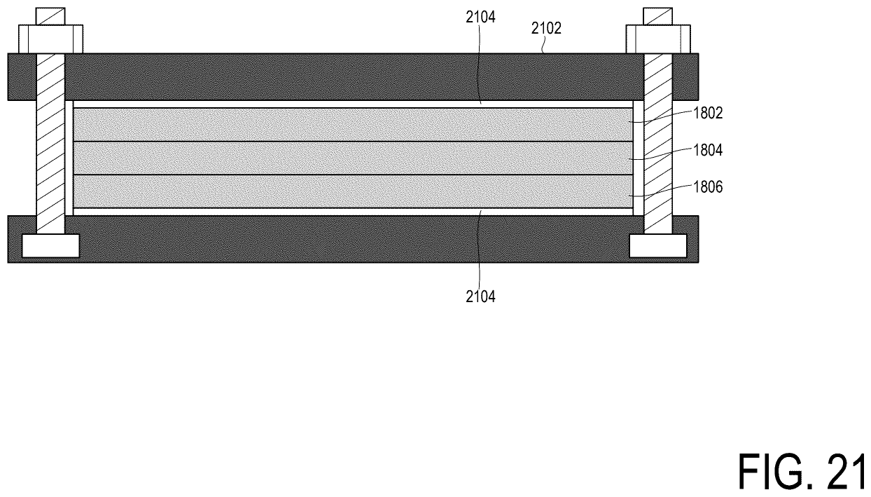

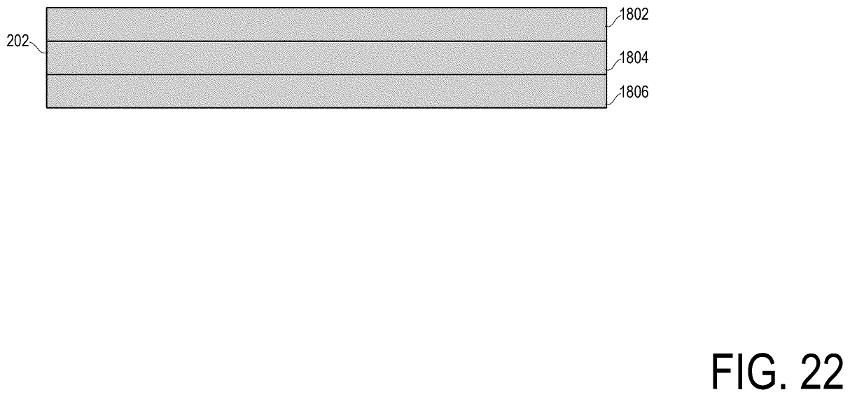

In block 1910, the glass sub-cores 1802, 1804, 1806 are stacked and placed in a clamp fixture 2102, as shown in FIG. 21. In some embodiments, graphite spacers 2104 may be placed on either side of the glass sub-cores 1802, 1804, 1806. In block 1912, a pre-bond soak is performed. In an illustrative embodiment, the pre-bond soak of the glass sub-cores 1802, 1804, 1806 is performed in a furnace at 450° C. with an applied force of 500 Newtons for 3 hours. In block 1914, the glass sub-cores 1802, 1804, 1806 are fusion bonded in a furnace at 550° C. for one hour. A force may be applied during the fusion process, such as a force of 0-500 Newtons. The fused glass core 202 with the sub-cores 1802, 1804, 1806 is then prepared, as shown in FIG. 22. It should be appreciated that, in an illustrative embodiment, the sub-cores 1802, 1804, 1806 are bonded by forming an oxide layer on the surface of the sub-cores 1802, 1804, 1804, which may be identified after bonding due to, e.g., increased oxygen at the interface of the sub-cores 1802, 1804, 1806.

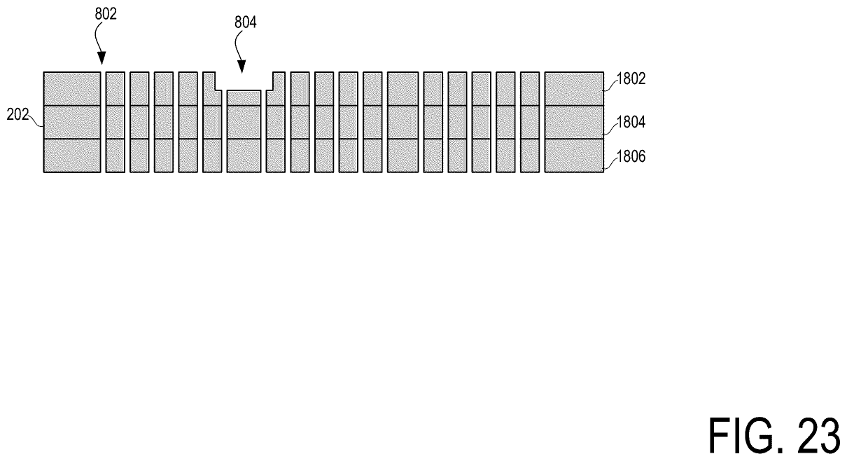

In block 1916, holes 802 and/or cavities 804 are formed in the substrate core, as shown in FIG. 23. In an illustrative embodiment, laser-induced deep etching (LIDE) is used to form the holes 802 and/or the cavity 804. In other embodiments, other techniques may be used, such as laser drilling, mechanical drilling, etching, etc.

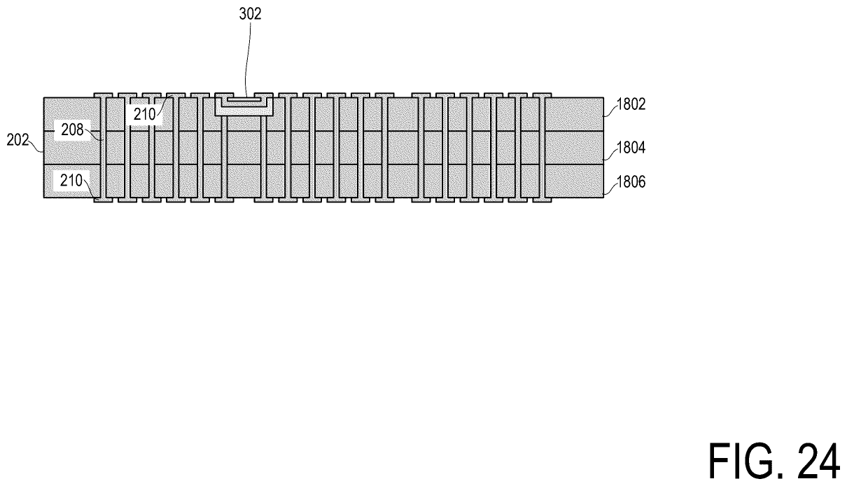

In block 1918, a bridge die 302 is placed in the cavity 804. In block 1920, vias 208, pads 210, and other traces are formed, as shown in FIG. 24. In an illustrative embodiment, the vias 208 and pads 210 may be formed by depositing a seed layer using electroless plating, patterning a photoresist, electroplating the seed layer, and then removing the photoresist and the remaining seed layer.

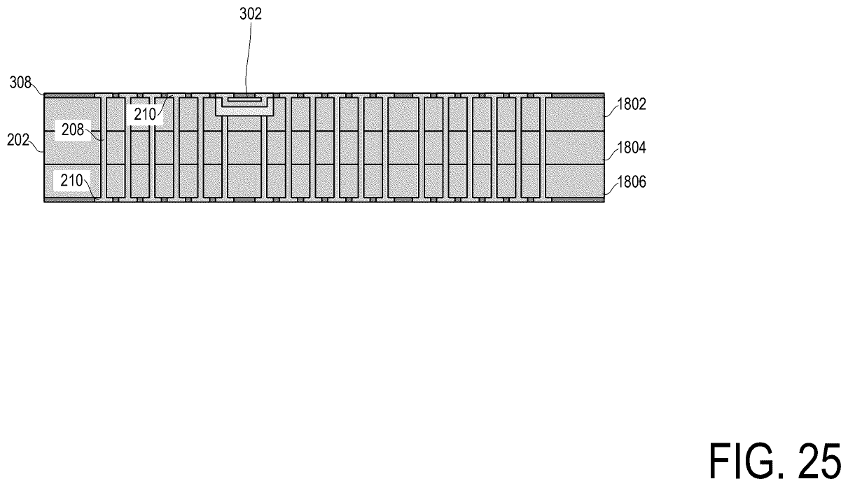

In block 1922, a polyimide layer 308 is deposited over the pads 210, creating a dielectric barrier between the pads 210 and other traces and higher layers of traces, as shown in FIG. 25.

In block 1924, the glass core 202 is attached to a temporary carrier 1102. In an illustrative embodiment, another glass core 202 is mounted on the other side of the temporary carrier 1102. Such an approach allows for forming build-up layers on two glass cores 202 at the same time. In some embodiments, a glass core 202 may be mounted only on one side of the carrier 1102. The temporary carrier 1102 may be any suitable material, such as glass, silicon, quartz, a ceramic, etc.

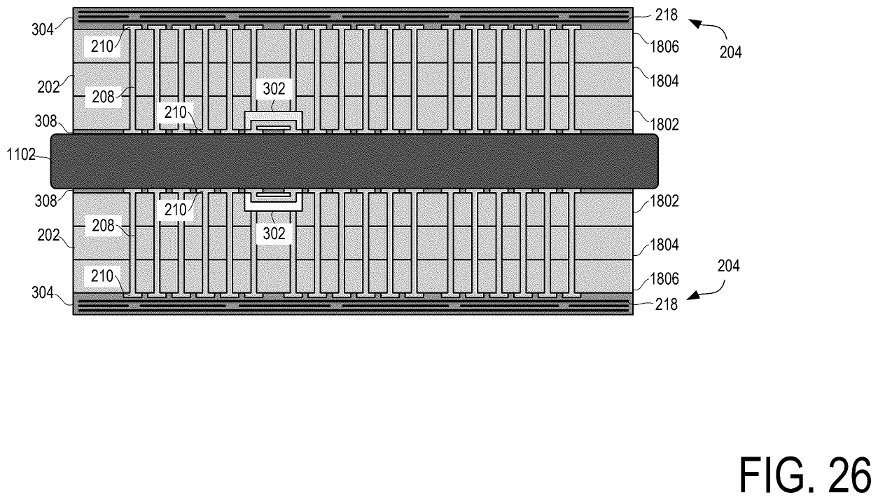

In block 1926, one or more fine redistribution layers 304 are formed on the glass core(s) 202, as shown in FIG. 26. Any suitable process may be used, such as embedded traces in polyimide or a semi-additive process on polyimide. The fine redistribution layers 304 may include traces, vias, pads, etc.

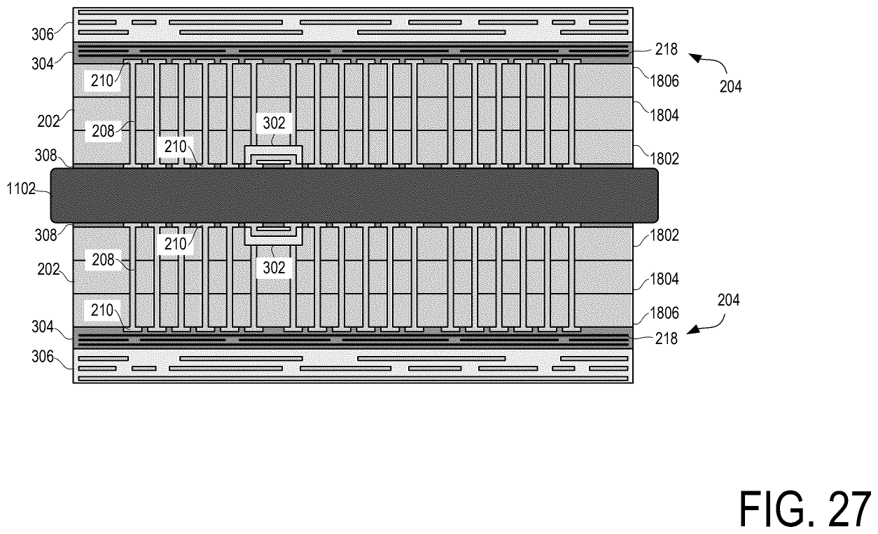

In block 1928, one or more coarse redistribution layers 306 are formed on the fine redistribution layers 304, as shown in FIG. 27. Any suitable process may be used, such as a semi-additive process on polyimide or using Ajinomoto build-up film (ABF).

It should be appreciated that, in an illustrative embodiment, the CTE of the build-up layers 204 matches that of the third glass sub-core 1806. As a result, in-process warpage is reduced or minimized.

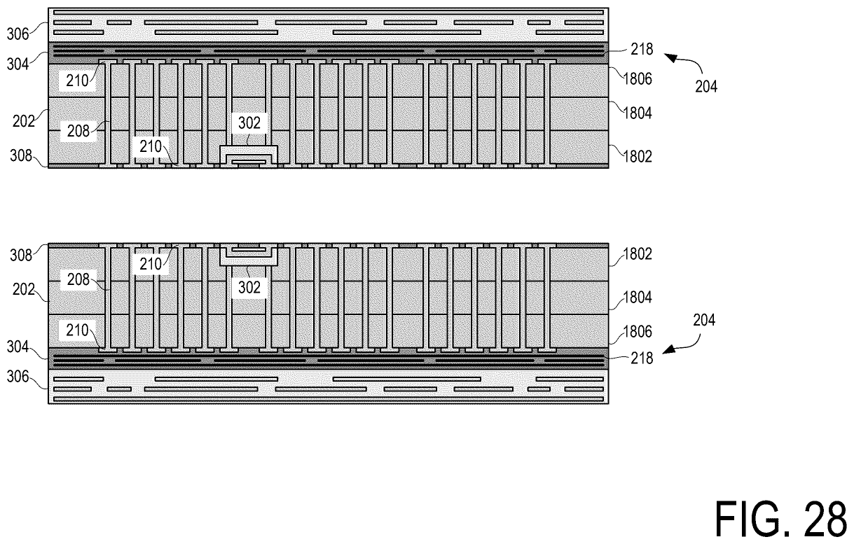

In block 1930, the glass core(s) 202 are detached from the temporary carrier, as shown in FIG. 28. In block 1932, dies 104 are mounted on the glass core 202, in a similar manner as for block 620, described above.

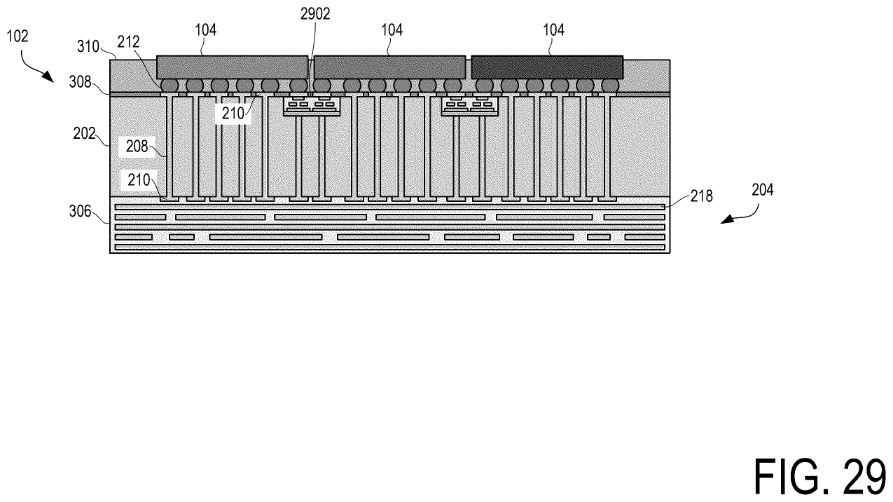

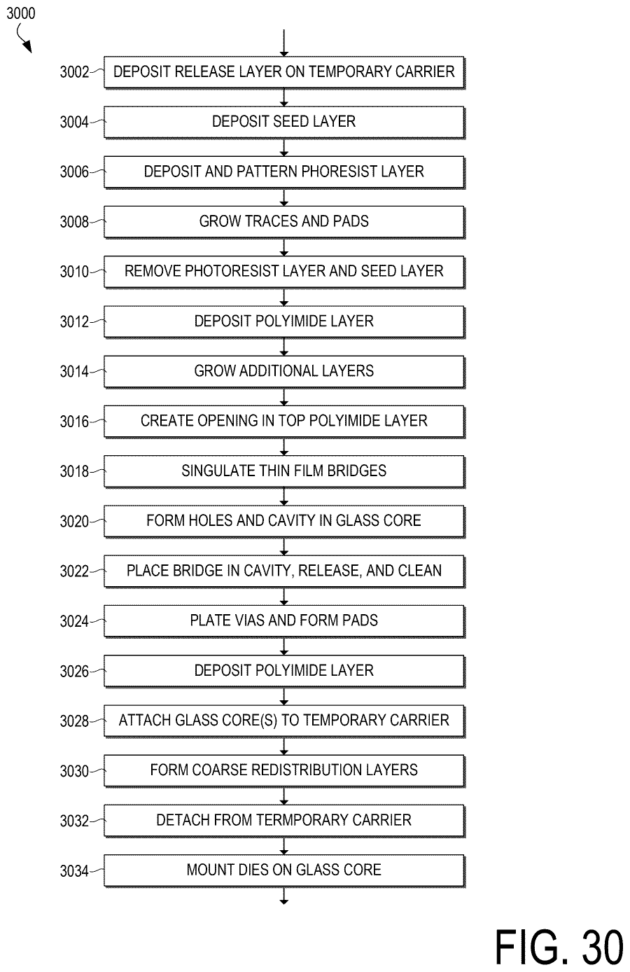

Referring now to FIG. 29, in one embodiment, an integrated circuit component 108 includes a thin-film bridge die 2902. In an illustrative embodiment, the bridge die 2902 may be built up on a substrate, such as a silicon substrate, as described in more detail below in regard to FIG. 30. Some or all of the substrate may be removed after the bridge die 2902 is placed in the glass core 202, resulting in a bridge die 2902 with thin film build-up layers without a separate substrate, or with only a thin substrate. It should be appreciated that the stiffness of the glass core 202 can maintain structural integrity for the bridge die 2902, keeping in place without significant warping or movement during processing and use. In contrast, with a bridge die in an organic substrate, a relatively thick substrate may be required for the bridge die in order for the bridge die to maintain structural integrity. As a result, the thin-film bridge die 2902 may have a thickness of, e.g., 5-20 micrometers, compared to 200-400 micrometers for a bridge die 302 with a silicon substrate to provide support. Additionally, as there is no silicon substrate, through-silicon vias are not required in order to provide connections to the bottom of the bridge die 2902. As a result, vias 208 in the glass core 202 can connect directly to pads in the base layer of the bridge die 2902. The bridge die 2902 may be created using back-end-of-line (BEOL) processes, with smaller feature sizes and higher cost, or semi-additive processes (SAP), with large feature sizes but lower cost. IN some embodiments, a bridge die 2902 with SAP may provide better signal integrity and may be preferred for die-to-die interconnect using a high frequency signal, such as UCIE-A at 32 Gbps/lane. The thin-film bridge die 2902 may have no Z height or lateral routing blockage implications. In some embodiments, a metal-insulator-metal (MIM) capacitor may be integrated into the bridge die 302, or a thin-film MIM capacitor die may be formed in a similar manner as the bridge die 302 and integrated into the glass core 202 in a similar manner as the bridge die 302

Referring now to FIG. 30, in one embodiment, a flowchart for a method 3000 for creating the integrated circuit component 108 is shown. The method 3000 may be executed by a technician and/or by one or more automated machines. In some embodiments, one or more machines may be programmed to do some or all of the steps of the method 3000. Such a machine may include, e.g., a memory, a processor, data storage, etc. The memory and/or data storage may store instructions that, when executed by the machine, cause the machine to perform some or all of the steps of the method 3000. The method 3000 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 3000 is merely one embodiment of a method to create one embodiment of a system, and other methods may be used to create any suitable embodiment of the system. In some embodiments, steps of the method 3000 may be performed in a different order than that shown in the flowchart.

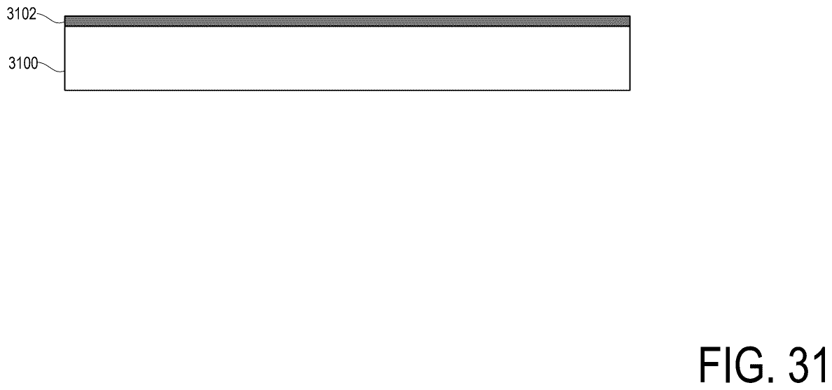

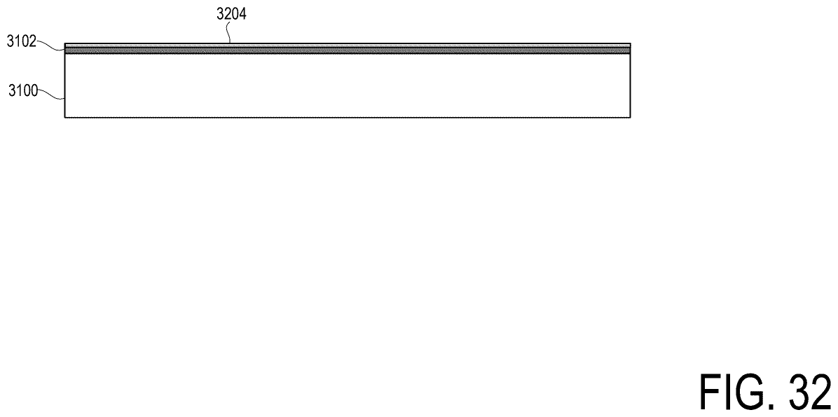

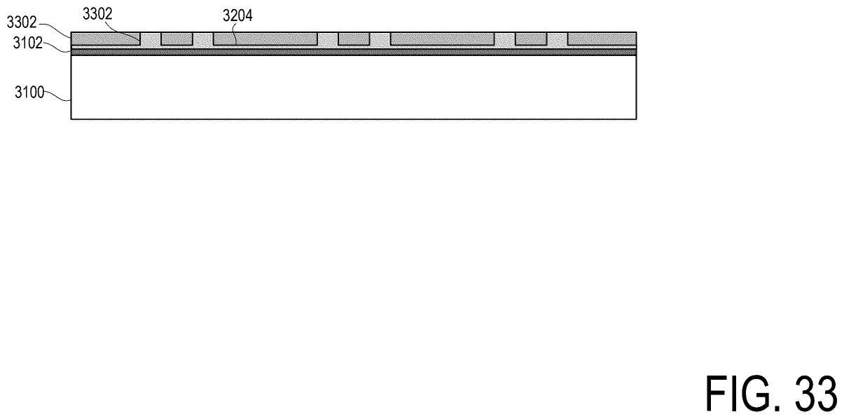

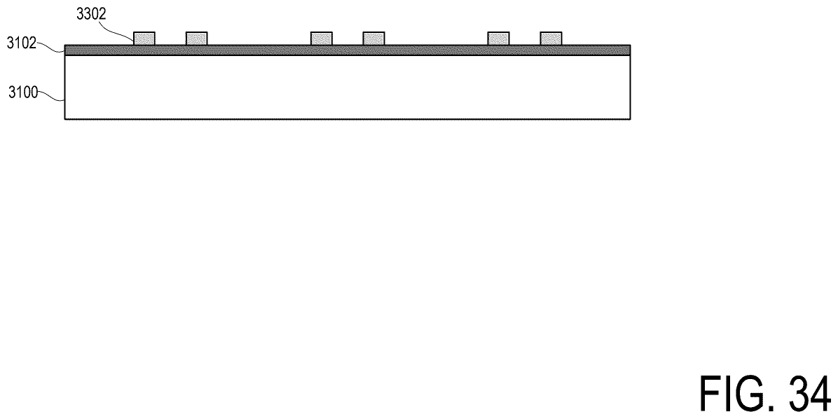

The method 3000 begins in block 3002, in which a release layer 3102 may be deposited on a temporary carrier 3100, as shown in FIG. 31. In block 3004, a seed layer 3204 is deposited, as shown in FIG. 32. In block 3006, a photoresist layer 3302 is deposited and patterned. In block 3008, traces and pads are grown, as shown in FIG. 33. In block 3010, the photoresist layer 3302 and the rest of the seed layer 3204 is removed, as shown in FIG. 34.

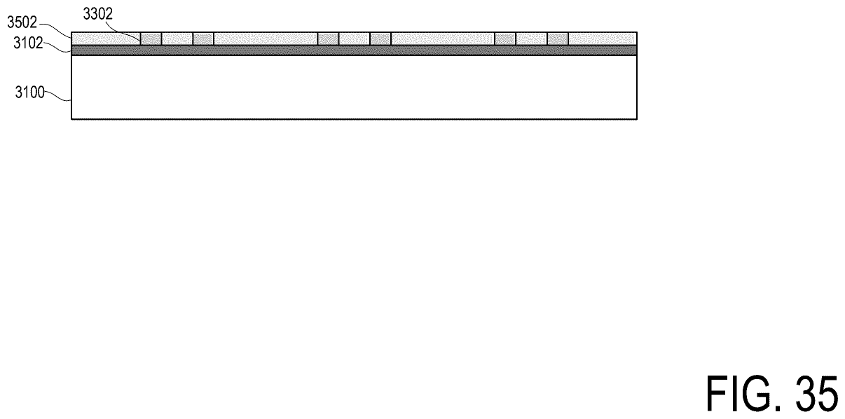

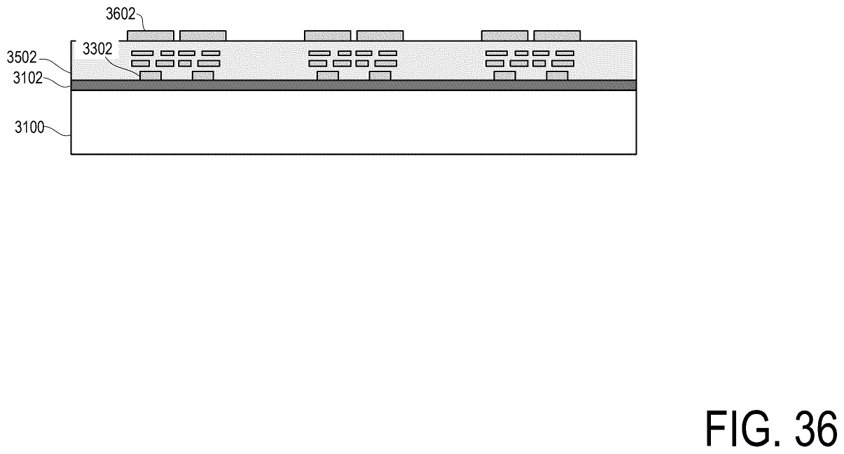

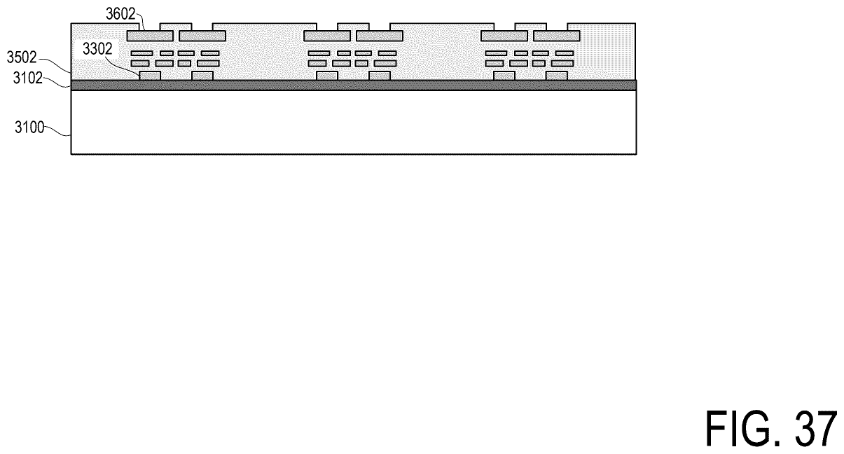

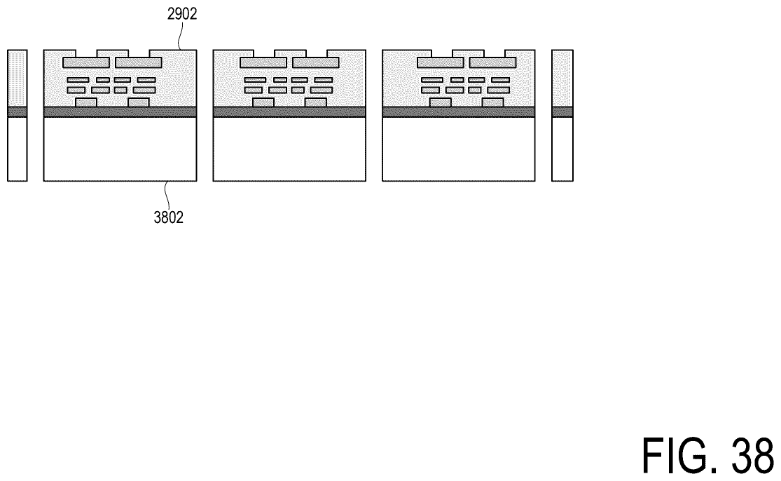

In block 3012, a polyimide layer 3502 is deposited, as shown in FIG. 35. In block 3014, additional layers are grown using a similar process as that described above, as shown in FIG. 36. A top polyimide layer may be applied and, in block 3016, an opening may be created in the top polyimide layer to expose the pads 3602, as shown in FIG. 37. In block 3018, the carrier 3100 and build-up layers may be singulated, forming the thin-film bridge dies 2902 on a carrier die 3802, as shown in FIG. 38.

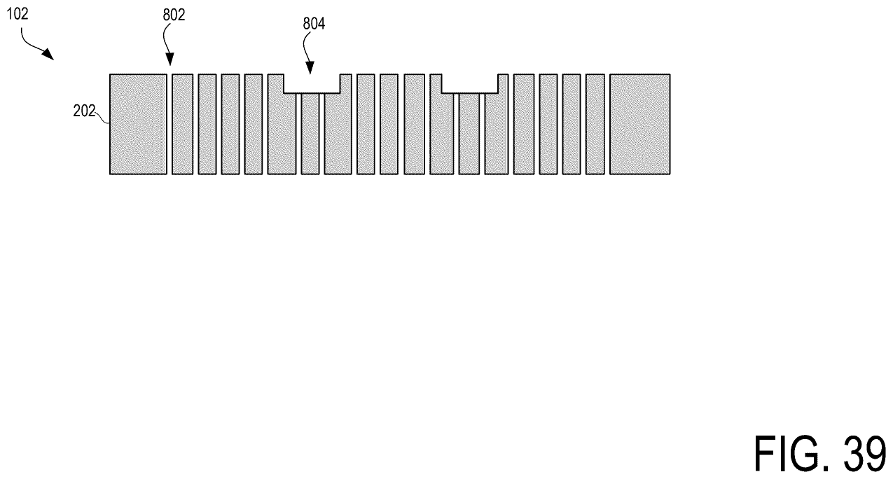

In block 3020, holes 802 and/or cavities 804 are formed in the substrate core, as shown in FIG. 39. In an illustrative embodiment, laser-induced deep etching (LIDE) is used to form the holes 802 and/or the cavity 804. In other embodiments, other techniques may be used, such as laser drilling, mechanical drilling, etching, etc. It should be appreciated that the cavity 804 can be relatively shallow, as the thin-film bridge die 2902 is not very thick. As such, forming the cavity 804 may be simpler and/or less expensive that forming a deeper cavity 804.

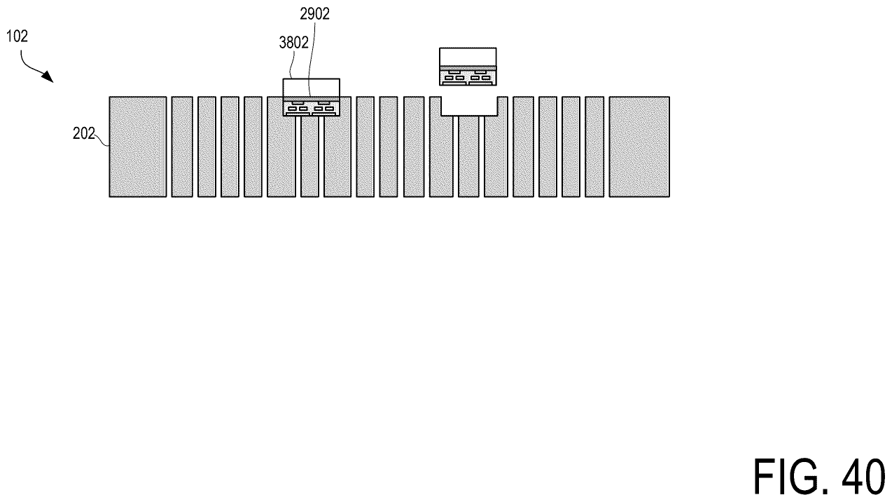

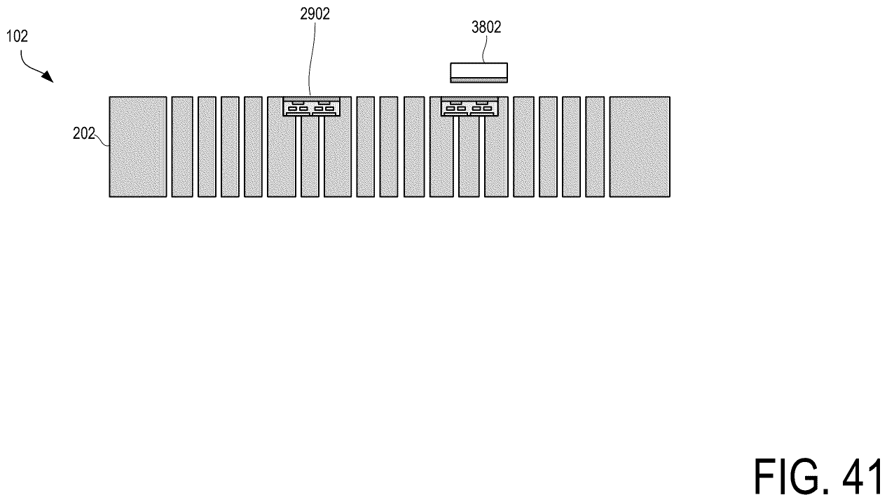

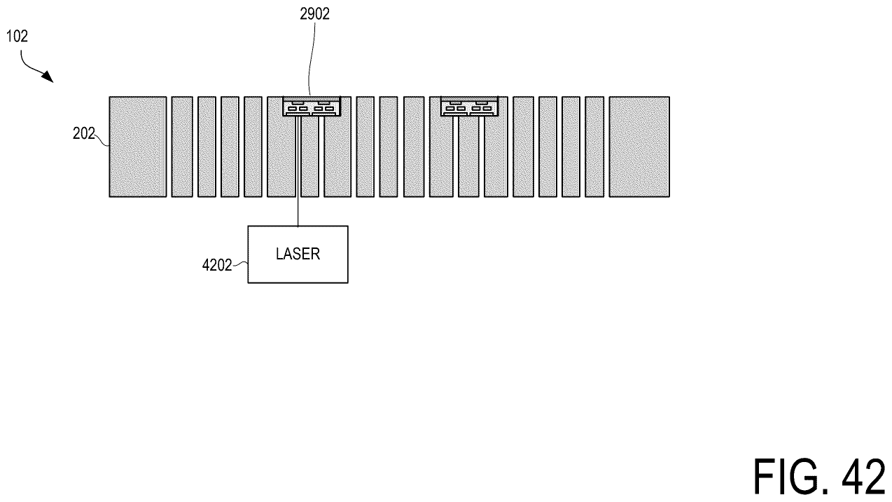

In block 3022, a thin-film bridge die 2902 is placed in the cavity 804, as shown in FIG. 40. In an illustrative embodiment, an adhesive, such as die attach film, may be placed on the thin-film bridge die 2902 and/or the bottom of the cavity 804 in order to secure the thin-film bridge die 2902. The carrier die 3802 may then be released from the thin-film bridge die 2902, as shown in FIG. 41. In some embodiments, the pads 3602 on the back side of the thin-film bridge die 2902 may be cleaned, such as by using a laser 4202, as shown in FIG. 42, or a chemical cleaner or etchant. In some embodiments, some of the adhesive securing the thin-film bridge die 2902 to the cavity 804 may be removed at this step, exposing the pads 3602.

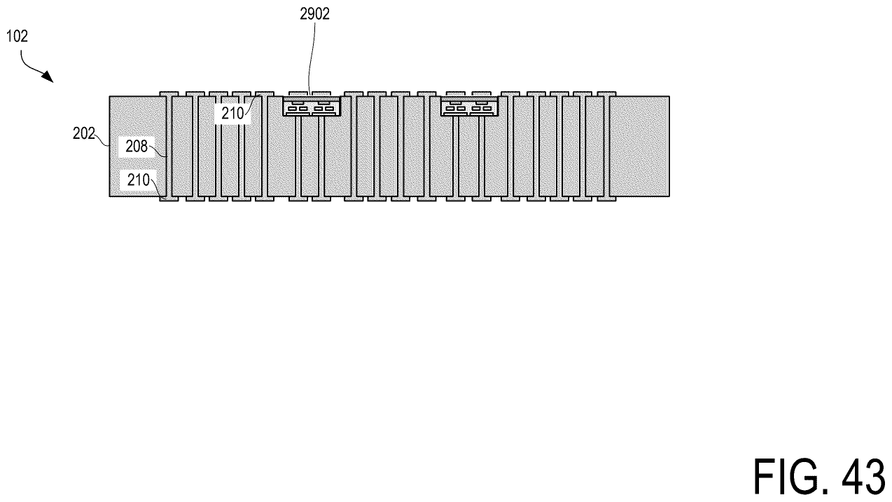

In block 3024, vias 208, pads 210, and other traces are formed, as shown in FIG. 43. In an illustrative embodiment, the vias 208 and pads 210 may be formed by depositing a seed layer using electroless plating, patterning a photoresist, electroplating the seed layer, and then removing the photoresist and the remaining seed layer.

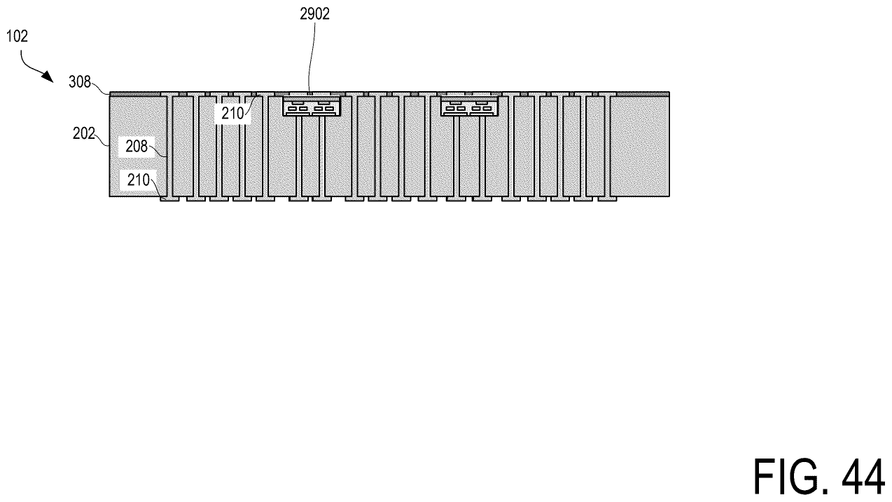

In block 3026, a polyimide layer 308 is deposited over the pads 210, creating a dielectric barrier between the pads 210 and other traces and higher layers of traces, as shown in FIG. 44.

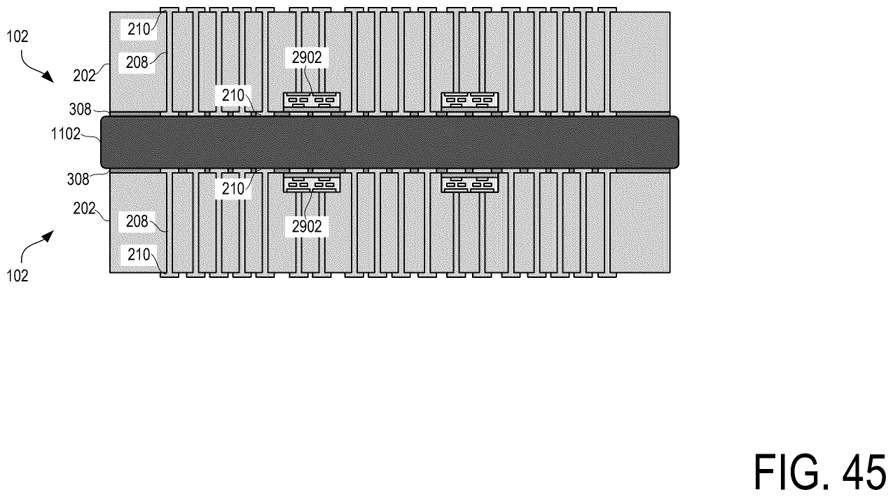

In block 3028, the glass core 202 is attached to a temporary carrier 1102. In an illustrative embodiment, another glass core 202 is mounted on the other side of the temporary carrier 1102, as shown in FIG. 45. Such an approach allows for forming build-up layers on two glass cores 202 at the same time. In some embodiments, a glass core 202 may be mounted only on one side of the carrier 1102. The temporary carrier 1102 may be any suitable material, such as glass, silicon, quartz, a ceramic, etc.

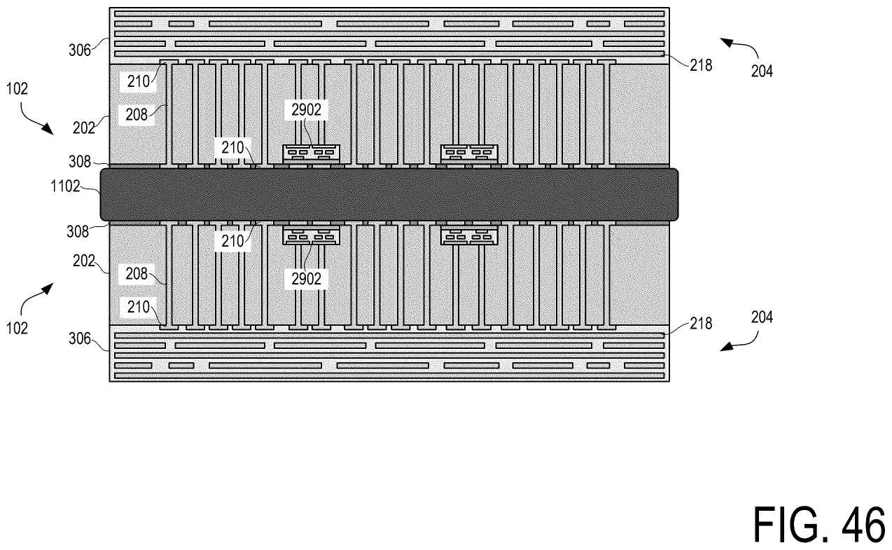

In block 3030, one or more coarse redistribution layers 306 are formed on the glass core 202, as shown in FIG. 46. Any suitable process may be used, such as a semi-additive process on polyimide or using Ajinomoto build-up film (ABF).

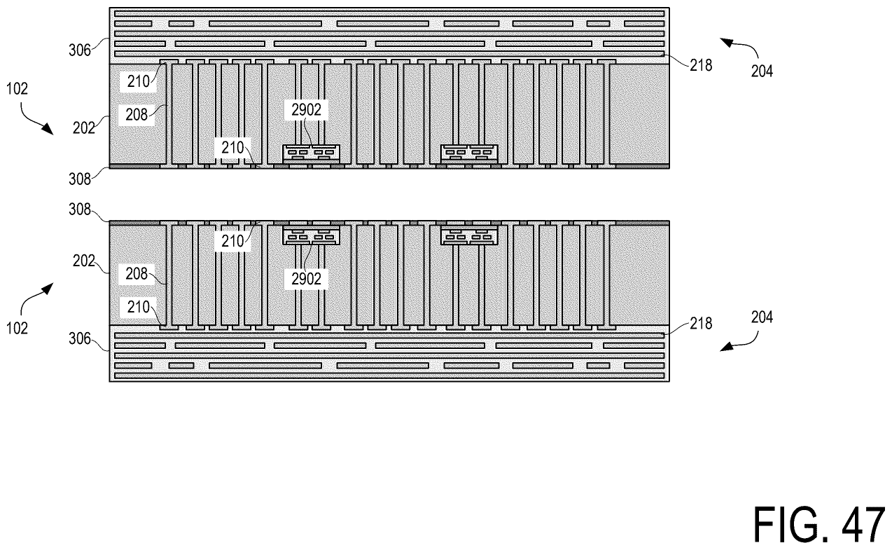

In block 3032, the glass core(s) 202 are detached from the temporary carrier, as shown in FIG. 47. In block 3034, dies 104 are mounted on the glass core 202 in a similar manner as for block 620, described above.

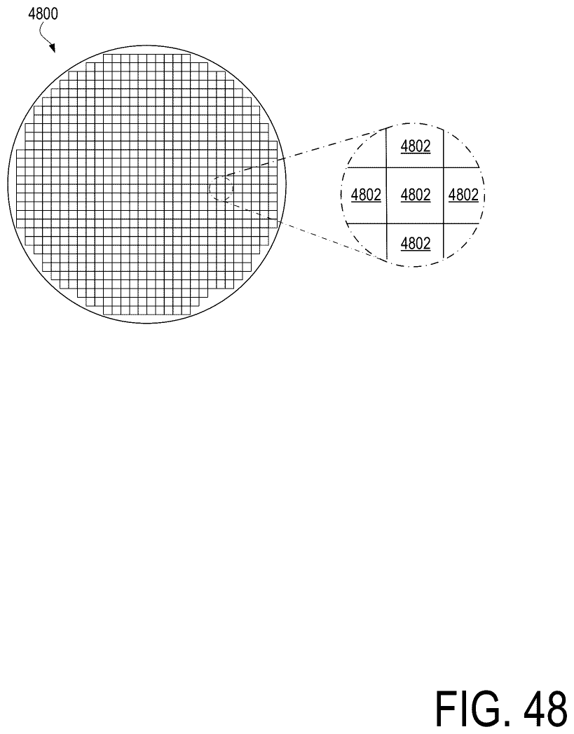

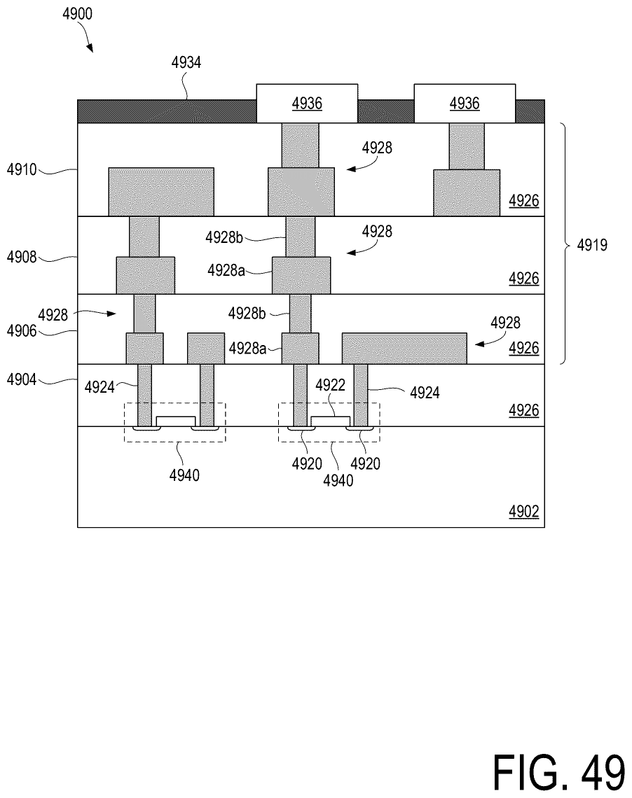

FIG. 48 is a top view of a wafer 4800 and dies 4802 that may be included in any of the integrated circuit components 108 disclosed herein (e.g., as any suitable ones of the dies 104). The wafer 4800 may be composed of semiconductor material and dies 4802 having integrated circuit structures formed on a surface of the wafer 4800. The individual dies 4802 may be a repeating unit of an integrated circuit product that includes any suitable integrated circuit. After the fabrication of the semiconductor product is complete, the wafer 4800 may undergo a singulation process in which the dies 4802 are separated from one another to provide discrete “chips” of the integrated circuit product. The dies 4802 may be any of the dies 104 disclosed herein. The dies 4802 may include one or more transistors (e.g., transistors 4940 of FIG. 49, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 4800 or the dies 4802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the integrated circuit components 108 disclosed herein may be manufactured using a die-to-wafer assembly technique in which some dies 104 are attached to a wafer 4800 that include others of the dies 104, and the wafer 4800 is subsequently singulated.

FIG. 49 is a cross-sectional view of an integrated circuit structure 4900 that may be included in any of the integrated circuit components 108 disclosed herein (e.g., in any of the dies 104). Multiple instances of the integrated circuit structure 4900 may be included in the dies 4802 (FIG. 48). The integrated circuit structure 4900 may be formed on a die substrate 4902. The die substrate 4902 may be a semiconductor substrate composed of semiconductor material including, for example, n-type or p-type materials (or a combination of both). The die substrate 4902 may include, for example, a crystalline substrate formed using a bulk silicon or a silicon-on-insulator (SOI) substructure. In some embodiments, the die substrate 4902 can comprise a layer of silicon on top of an SOI layer with bulk silicon below the SOI layer. In some embodiments, the die substrate 4902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 4902. Although a few examples of materials from which the die substrate 4902 may be formed are described here, any material that may serve as a foundation for an integrated circuit structure 4900 may be used. The die substrate 4902 may be part of a singulated die (e.g., dies 4802 of FIG. 48) or a wafer (e.g., wafer 4800 of FIG. 48).

The integrated circuit structure 4900 may include device layer 4904 disposed on the die substrate 4902. The device layer 4904 may include features of transistors 4940 (e.g., metal oxide semiconductor field-effect transistors (MOSFETs)) formed on the die substrate 4902. The transistors 4940 may include, for example, source and drain regions (S/D regions 4920), a gate 4922 to control current flow between the S/D regions 4920, and S/D contacts 4924 to route electrical signals to and from the S/D regions 4920. The transistors 4940 may include additional features not depicted for the sake of clarity, such as device isolation regions, gate contacts, and the like. The transistors 4940 are not limited to the type and configuration depicted in FIG. 49 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

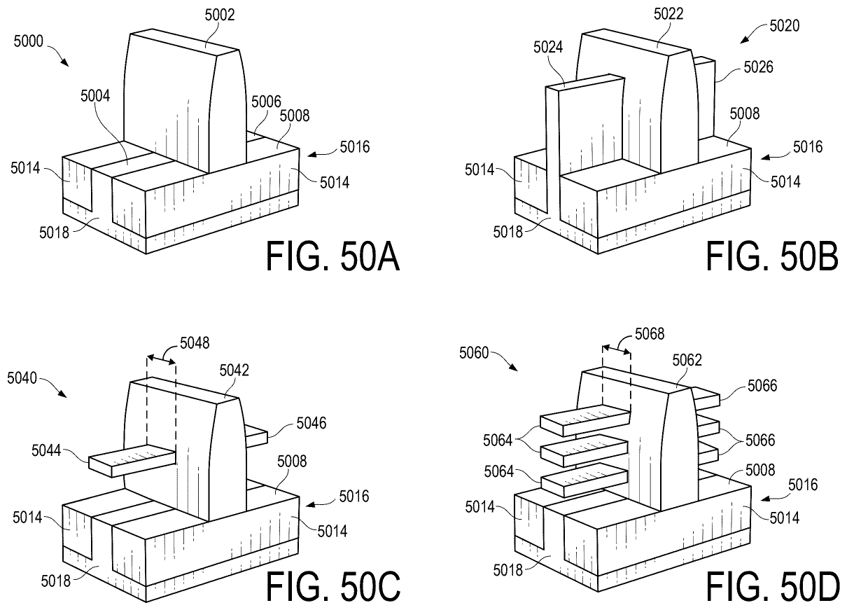

FIGS. 50A-50D are perspective views of example planar, FinFET, gate-all-around, and stacked gate-all-around transistors. The transistors illustrated in FIGS. 50A-50D are formed on a substrate 5016 having a substrate surface 5008 and a bulk region 5018. Isolation regions 5014 separate the source and drain regions of the transistors from other transistors.

FIG. 50A is a perspective view of an example transistor 5000 comprising a gate 5002 that controls current flow between a source region 5004 and a drain region 5006. The transistor 5000 is planar in that the source region 5004, the drain region 5006 and the substrate surface 5008 lie in the same plane.

FIG. 50B is a perspective view of an example transistor 5020 comprising a gate 5022 that controls current flow between a source region 5024 and a drain region 5026. The transistor 5020 is non-planar in that the source region 5024 and the drain region 5026 comprise “fins” that extend upwards from the substrate surface 5008. The transistor 5020 can be referred to as a FinFET. As the gate 5022 encompasses three sides of the fin that extends from the source region 5024 to the drain region 5026, the transistor 5020 can be considered a tri-gate transistor. FIG. 50B illustrates one S/D fin extending through the gate 5022, but multiple S/D fins can extend through the gate of a FinFET transistor.

FIG. 50C is a perspective view of a transistor 5040 comprising a gate 5042 that controls current flow between a source region 5044 and a drain region 5046. The transistor 5040 is non-planar in that the source region 5044 and the drain region 5046 lie in a different plane than the substrate surface 5008. As the gate 5042 encompasses all sides of the channel region of the transistor 5040 that extends from the source region 5044 to the drain region 5046, the transistor 5040 can be referred to as a gate-all-around (GAA) transistor.

FIG. 50D is a perspective view of a transistor 5060 comprising a gate 5062 that controls current flow between multiple elevated source regions 5064 and multiple elevated drain regions 5066. The transistor 5060 is a stacked GAA transistor as the gate controls the flow of current between multiple elevated S/D regions stacked on top of each other. The transistors 5040 and 5060 are considered gate-all-around transistors as the gates encompass all sides of the channel regions of the transistor that extends from the source regions to the drain regions. The transistors 5040 and 5060 can alternatively be referred to as nanowire, nanosheet, or nanoribbon transistors depending on the width (e.g., widths 5048 and 5068 of transistors 5040 and 5060, respectively) of the channel regions extending through the gate.

Returning to FIG. 49, transistors 4940 may include a gate 4922 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 50B, the gate electrode may have an upside-down U-shape that includes a top portion substantially parallel to the surface of the die substrate 4902 and two side portions that are substantially perpendicular to the top surface of the die substrate 4902. In other embodiments, such as the planar FET illustrated in FIG. 50A, at least one of the metal layers that form the gate electrode may be a planar layer that is substantially parallel to the top surface of the die substrate 4902 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 4920 may be formed within the die substrate 4902 adjacent to the gate 4922 of transistors 4940. The S/D regions 4920 may be formed using an implantation/diffusion process or an etching/deposition process, for example. In the former process, dopants such as boron, aluminum, antimony, phosphorous, or arsenic may be ion-implanted into the die substrate 4902 to form the S/D regions 4920. An annealing process that activates the dopants and causes them to diffuse further into the die substrate 4902 may follow the ion implantation process. In the latter process, the die substrate 4902 may first be etched to form recesses at the locations of the S/D regions 4920. An epitaxial deposition process may then be carried out to fill the recesses with material that is used to fabricate the S/D regions 4920. In some implementations, the S/D regions 4920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 4920 may be formed using one or more alternate semiconductor materials such as germanium or a group III-V material or alloy. In further embodiments, one or more layers of metal and/or metal alloys may be used to form the S/D regions 4920.

Electrical signals, such as power and/or information-carrying signals (e.g., input/output (I/O) signals, may be routed to and/or from devices (e.g., transistors 4940) of the device layer 4904 through one or more interconnect layers disposed on the device layer 4904 (illustrated in FIG. 49 as interconnect layers 4906-4910). For example, electrically conductive features of the device layer 4904 (e.g., the gate 4922 and the S/D contacts 4924) may be electrically coupled with interconnect structures 4928 of the interconnect layers 4906-4910. The one or more interconnect layers 4906-4910 may form a metallization stack 4919 (which can also be referred to as an “ILD stack” (inter-layer dielectric stack)) of the integrated circuit structure 4900.

The interconnect structures 4928 may be arranged within the interconnect layers 4906-4910 to route electrical signals according to a wide variety of designs; in particular, the arrangement is not limited to the particular configuration of interconnect structures 4928 depicted in FIG. 49. Although a particular number of interconnect layers 4906-4910 is depicted in FIG. 49, embodiments of the present disclosure include integrated circuit structures having more or fewer interconnect layers than depicted.

In some embodiments, the interconnect structures 4928 may include traces or lines 4928a and/or vias 4928b filled with an electrically conductive material such as a metal. The lines 4928a may be arranged to route electrical signals in a direction of a plane that is substantially parallel with a surface of the die substrate 4902 upon which the device layer 4904 is formed. For example, the lines 4928a may route electrical signals in a direction in and out of the page and/or in a direction across the page from the perspective of FIG. 49. The vias 4928b may be arranged to route electrical signals in a direction of a plane that is substantially perpendicular to the surface of the die substrate 4902 upon which the device layer 4904 is formed. In some embodiments, lines 4928a of different interconnect layers 4906-4910 are electrically coupled by vias 4928b.

The interconnect layers 4906-4910 may include a dielectric material 4926 within which the interconnect structures 4928 are disposed, as shown in FIG. 49. In some embodiments, dielectric material 4926 in different ones of the interconnect layers 4906-4910 may have different compositions; in other embodiments, the composition of the dielectric material 4926 between different interconnect layers 4906-4910 may be the same. The device layer 4904 may include a dielectric material 4926 within which the transistors 4940 are disposed and upon which a bottom layer of the metallization stack is located. The dielectric material 4926 that is part of the device layer 4904 may have a different composition than the dielectric material 4926 included in the interconnect layers 4906-4910; in other embodiments, the composition of the dielectric material 4926 in the device layer 4904 may be the same as a dielectric material 4926 included in any one of the interconnect layers 4906-4910.

A first interconnect layer 4906 (which can be referred to as a Metal 1 or “M1” layer) may be formed directly on the device layer 4904. In some embodiments, the first interconnect layer 4906 may include lines 4928a and/or vias 4928b, as shown. The lines 4928a of the first interconnect layer 4906 may be coupled with contacts (e.g., the S/D contacts 4924) of the device layer 4904. The vias 4928b of the first interconnect layer 4906 may be coupled with the lines 4928a of a second interconnect layer 4908.

The second interconnect layer 4908 (which can be referred to as a Metal 2 or “M2” layer) may be formed directly on the first interconnect layer 4906. In some embodiments, the second interconnect layer 4908 may include vias 4928b to couple the lines 4928a of the second interconnect layer 4908 with the lines 4928a of a third interconnect layer 4910. Although the lines 4928a and the vias 4928b are structurally delineated with a line within individual interconnect layers for the sake of clarity, the lines 4928a and the vias 4928b may be structurally and/or materially contiguous (e.g., simultaneously filled during a dual-damascene process) in some embodiments.

The third interconnect layer 4910 (which can be referred to as a Metal 3 or “M3” layer) (and additional interconnect layers, as desired) may be formed in succession on the second interconnect layer 4908 according to similar techniques and configurations described in connection with the second interconnect layer 4908 or the first interconnect layer 4906. In some embodiments, the interconnect layers that are “higher up” in the metallization stack 4919 in the integrated circuit structure 4900 (i.e., farther away from the device layer 4904) may be thicker than the interconnect layers that are lower in the metallization stack 4919, with lines 4928a and vias 4928b in the higher interconnect layers being thicker than those in the lower interconnect layers.

The integrated circuit structure 4900 may include a solder resist material 4934 (e.g., polyimide or similar material) and conductive contacts 4936 formed on the stack of interconnect layers 4906-4910. In FIG. 49, the conductive contacts 4936 are illustrated as taking the form of bond pads. The conductive contacts 4936 may be electrically coupled with interconnect structures 4928 of the top-most layer in the metallization stack 4919 and configured to route electrical signals between the transistors 4940 and components external to the integrated circuit structure 4900. For example, solder bonds may be formed on the conductive contacts 4936 to mechanically and/or electrically couple an integrated circuit component comprising the integrated circuit structure 4900 with another component (e.g., a printed circuit board). The integrated circuit structure 4900 may include additional or alternate structures to route electrical signals from the interconnect layers 4906-4910; for example, the conductive contacts 4936 may include other analogous features (e.g., posts) that can route the electrical signals between the transistors 4940 and external components. The conductive contacts 4936 may serve as the conductive contacts 212, as appropriate.

In some embodiments in which the integrated circuit structure 4900 is part of a double-sided die (e.g., like the die 104), the integrated circuit structure 4900 may include a second metallization stack (not shown) located on the opposite side of the die substrate 4902 from the device layer 4904. This second metallization stack may include multiple interconnect layers as discussed above with reference to the interconnect layers 4906-4910. Through-silicon vias (TSVs) that extend through the die substrate 4902 can provide electrically conductive pathways from the transistors 4940 to the second metallization stack and the second metallization stack can electrically couple the TSVs to additional conductive contacts (not shown) located on the opposite side of the integrated circuit structure 4900 from the conductive contacts 4936. These additional conductive contacts may serve as the conductive contacts 212, as appropriate.

In some embodiments, TSVs extending through the die substrate 4902 can be used for routing power and ground signals from conductive contacts located on the opposite side of the integrated circuit structure 4900 from the conductive contacts 4936 to the transistors 4940 and any other components integrated into the integrated circuit structure 4900, and the metallization stack 4919 can be used to route information-carrying signals from the conductive contacts 4936 to transistors 4940 and any other components integrated into the integrated circuit structure 4900. Put another way, the routing of power and ground signals to the transistors 4940 can be separated (via a back-side or bottom-side metallization stack and TSVs) from the routing of information-carrying signals to the transistors. The power and ground signals are provided by a back-side or bottom-side metallization stack and TSVs, and information-carrying signals are provide by a top-side metallization stack (e.g., metallization stack 4919).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

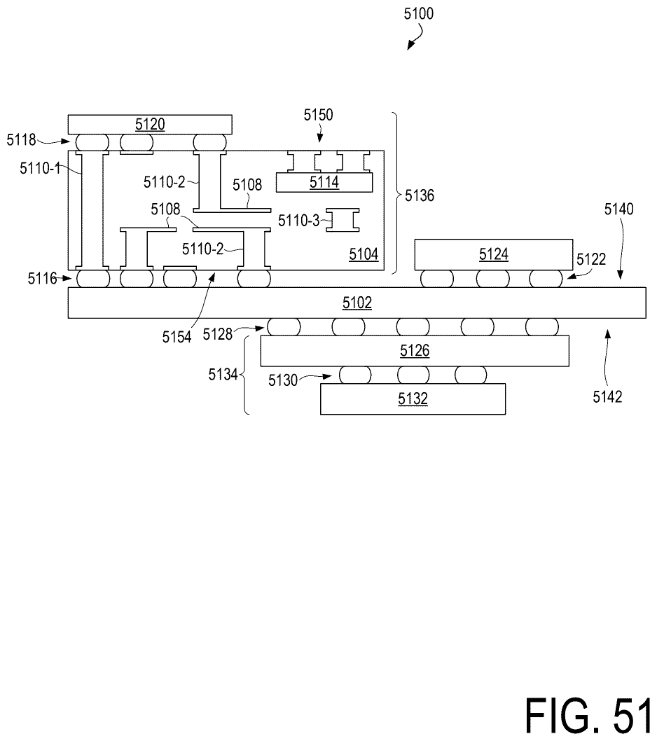

FIG. 51 is a cross-sectional view of an integrated circuit device assembly 5100 that may include any of the integrated circuit components 108 disclosed herein. In some embodiments, the integrated circuit device assembly 5100 may be an integrated circuit component 108. The integrated circuit device assembly 5100 includes a number of components disposed on a circuit board 5102 (which may be a motherboard, system board, mainboard, etc.). The integrated circuit device assembly 5100 includes components disposed on a first face 5140 of the circuit board 5102 and a second face 5142 of the circuit board 5102, the second face 5142 opposing the first face 5140. Generally, components may be disposed on either or both of the first face 5140 and the second face 5142 of the circuit board 5102. Any of the integrated circuit components discussed below with reference to the integrated circuit device assembly 5100 may take the form of any suitable ones of the embodiments of the integrated circuit components 108 disclosed herein.

In some embodiments, the circuit board 5102 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 5102. In other embodiments, the circuit board 5102 may be a non-PCB substrate. In some embodiments the circuit board 5102 may be, for example, the circuit board 106.

The integrated circuit device assembly 5100 illustrated in FIG. 51 includes a package-on-interposer structure 5136 coupled to the first face 5140 of the circuit board 5102 by coupling components 5116. The coupling components 5116 may electrically and mechanically couple the package-on-interposer structure 5136 to the circuit board 5102 and may include solder balls (as shown in FIG. 51), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 5116 may serve as the coupling components illustrated or described for any substrate assembly or substrate assembly components described herein (e.g., integrated circuit components), as appropriate.

The package-on-interposer structure 5136 may include an integrated circuit component 5120 coupled to an interposer 5104. The interposer 5104 may provide an intervening substrate used to bridge the circuit board 5102 and the integrated circuit component 5120. The integrated circuit component 5120 is coupled to the interposer 5104 by coupling components 5118. The coupling components 5118 may take any suitable form, such as the forms discussed above with reference to the coupling components 5116. Although FIG. 51 shows just one integrated circuit component attached to the interposer, multiple integrated circuit components may be coupled to the interposer 5104. Additional interposers may be coupled to the interposer 5104.

The integrated circuit component 5120 may be a packaged or unpacked integrated circuit product that includes one or more integrated circuit dies (e.g., the die 4802 of FIG. 48, a die comprising the integrated circuit structure 4900 of FIG. 49) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 5120, a single monolithic integrated circuit die comprises solder bumps attached to contacts on the die. The solder bumps allow the die to be directly attached to the interposer 5104. The integrated circuit component 5120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 5120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 5120 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 5120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 5104 may spread connections to a wider or narrower pitch or reroute a connection to a different connection. For example, the interposer 5104 may couple coupling components 5118 having a first pitch to coupling components 5116 having a wider pitch than the first pitch. In the embodiment illustrated in FIG. 51, the integrated circuit component 5120 and the circuit board 5102 are attached to opposing sides of the interposer 5104. In other embodiments, the integrated circuit component 5120 and the circuit board 5102 may be attached to a same side of the interposer 5104. In some embodiments, three or more components may be interconnected by way of the interposer 5104.

In some embodiments, the interposer 5104 may be formed as a PCB, including multiple metal layers separated from one another by layers of dielectric material and interconnected by electrically conductive vias. In some embodiments, the interposer 5104 may be formed of an epoxy resin, a fiberglass-reinforced epoxy resin, an epoxy resin with inorganic fillers, a ceramic material, or a polymer material such as polyimide. In some embodiments, the interposer 5104 may be formed of alternate rigid or flexible materials that may include the same materials described above for use in a semiconductor substrate, such as silicon, germanium, and other group III-V and group IV materials. The interposer 5104 may include metal interconnects 5108 and vias, including but not limited to through hole vias 5110-1 (that extend from a first face 5150 of the interposer 5104 to a second face 5154 of the interposer 5104), blind vias 5110-2 (that extend from the first face 5150 or the second face 5154 of the interposer 5104 to an internal metal layer), and buried vias 5110-3 (that connect internal metal layers).

In some embodiments, the interposer 5104 can comprise a silicon interposer. Through silicon vias (TSV) extending through the silicon interposer can connect connections on a first face of a silicon interposer to an opposing second face of the silicon interposer. In some embodiments, an interposer 5104 comprising a silicon interposer can further comprise one or more routing layers to route connections on a first face of the interposer 5104 to an opposing second face of the interposer 5104.

In some embodiments the interposer 5104, as well as the circuit board 5102, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin (IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 5104 or circuit board 5102 to the glass layer. The glass layer can comprise through-glass vias (TGVs) that extend through the glass layer to provide electrically conductive paths through the glass core, glass substrate, or glass layer.

The interposer 5104 may further include embedded devices 5114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 5104. The package-on-interposer structure 5136 may take the form of any of the package-on-interposer structures known in the art.

The integrated circuit device assembly 5100 may include an integrated circuit component 5124 coupled to the first face 5140 of the circuit board 5102 by coupling components 5122. The coupling components 5122 may take the form of any of the embodiments discussed above with reference to the coupling components 5116, and the integrated circuit component 5124 may take the form of any of the embodiments discussed above with reference to the integrated circuit component 5120.

The integrated circuit device assembly 5100 illustrated in FIG. 51 further includes a package-on-package structure 5134 coupled to the second face 5142 of the circuit board 5102 by coupling components 5128. The package-on-package structure 5134 may include an integrated circuit component 5126 and an integrated circuit component 5132 coupled together by coupling components 5130 such that the integrated circuit component 5126 is disposed between the circuit board 5102 and the integrated circuit component 5132. The coupling components 5128 and 5130 may take the form of any of the embodiments of the coupling components 5116 discussed above, and the integrated circuit components 5126 and 5132 may take the form of any of the embodiments of the integrated circuit component 5120 discussed above. The package-on-package structure 5134 may be configured in accordance with any of the package-on-package structures known in the art.

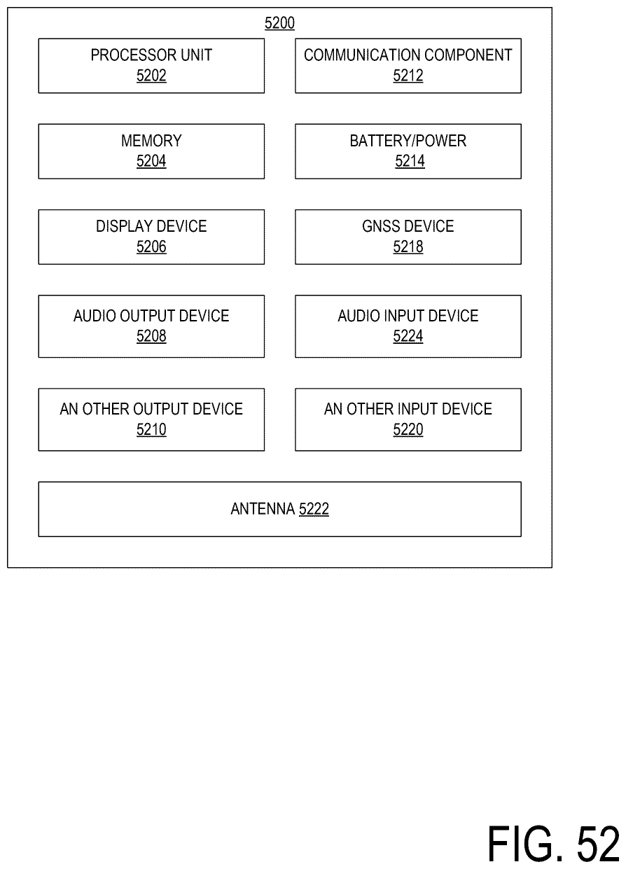

FIG. 52 is a block diagram of an example electrical device 5200 that may include any of the microelectronic assemblies disclosed herein. For example, any suitable ones of the components of the electrical device 5200 may include one or more of the integrated circuit device assembly 5100, integrated circuit component 5120, or integrated circuit structure 4900, integrated circuit dies 4802 disclosed herein, and may be arranged in any of the integrated circuit components 108 disclosed herein. A number of components are illustrated in FIG. 52 as included in the electrical device 5200, but any one or more of these components may be omitted or duplicated, as suitable for the application. In some embodiments, some or all of the components included in the electrical device 5200 may be attached to one or more motherboards mainboards, or system boards. In some embodiments, one or more of these components are fabricated onto a single system-on-a-chip (SoC) die.

Additionally, in various embodiments, the electrical device 5200 may not include one or more of the components illustrated in FIG. 52, but the electrical device 5200 may include interface circuitry for coupling to the one or more components. For example, the electrical device 5200 may not include a display device 5206, but may include display device interface circuitry (e.g., a connector and driver circuitry) to which a display device 5206 may be coupled. In another set of examples, the electrical device 5200 may not include an audio input device 5224 or an audio output device 5208, but may include audio input or output device interface circuitry (e.g., connectors and supporting circuitry) to which an audio input device 5224 or audio output device 5208 may be coupled.

The electrical device 5200 may include one or more processor units 5202. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 5202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 5200 may include a memory 5204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 5204 may include memory that is located on the same integrated circuit die as the one or more processor units 5202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 5200, a first one of the one or more processor units 5202 can be heterogeneous or asymmetric to a second one of the one or more processor units 5202 in the electrical device 5200. There can be a variety of differences between the one or more processor units 5202 in a system in terms of a spectrum of metrics of merit including architectural, microarchitectural, thermal, power consumption characteristics, and the like. These differences can effectively manifest themselves as asymmetry and heterogeneity among the one or more processor units 5202 in the electrical device 5200.

In some embodiments, the electrical device 5200 may include a communication component 5212. For example, the communication component 5212 can manage wireless communications for the transfer of data to and from the electrical device 5200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 5212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 5212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 5212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 5212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 5212 may operate in accordance with other wireless protocols in other embodiments. The electrical device 5200 may include an antenna 5222 to facilitate wireless communications and/or to receive other wireless communications (such as AM or FM radio transmissions).

In some embodiments, the communication component 5212 may manage wired communications, such as electrical, optical, or any other suitable communication protocols (e.g., IEEE 802.3 Ethernet standards). In some embodiments, the electrical device 5200 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 5200 may include battery/power circuitry 5214. The battery/power circuitry 5214 may include one or more energy storage devices (e.g., batteries or capacitors) and/or circuitry for coupling components of the electrical device 5200 to an energy source separate from the electrical device 5200 (e.g., AC line power).

The electrical device 5200 may include a display device 5206 (or corresponding interface circuitry, as discussed above). The display device 5206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 5200 may include an audio output device 5208 (or corresponding interface circuitry, as discussed above). The audio output device 5208 may include any embedded or wired or wirelessly connected external device that generates an audible indicator, such as speakers, headsets, or earbuds.

The electrical device 5200 may include an audio input device 5224 (or corresponding interface circuitry, as discussed above). The audio input device 5224 may include any embedded or wired or wirelessly connected device that generates a signal representative of a sound, such as microphones, microphone arrays, or digital instruments (e.g., instruments having a musical instrument digital interface (MIDI) output). The electrical device 5200 may include a Global Navigation Satellite System device (GNSS) (or corresponding interface circuitry, as discussed above), such as a Global Positioning System (GPS) device. The GNSS device 5218 may be in communication with a satellite-based system and may determine a geolocation of the electrical device 5200 based on information received from one or more GNSS satellites, as known in the art.

The electrical device 5200 may include another output device 5210 (or corresponding interface circuitry, as discussed above). Examples of the other output device 5210 may include an audio codec, a video codec, a printer, a wired or wireless transmitter for providing information to other devices, or an additional storage device.

The electrical device 5200 may include another input device 5220 (or corresponding interface circuitry, as discussed above). Examples of the other input device 5220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 5200 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 5200 may be any other electronic device that processes data. In some embodiments, the electrical device 5200 may comprise multiple discrete physical components. Given the range of devices that the electrical device 5200 can be manifested as in various embodiments, in some embodiments, the electrical device 5200 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a glass core, the glass core comprising a top side and a bottom side; one or more dies adjacent the top side of the glass core; and one or more build-up layers adjacent the bottom side.

Example 2 includes the subject matter of Example 1, and wherein the glass core has a first coefficient of thermal expansion (CTE), wherein the one or more dies have a second CTE, wherein the first CTE is within 1 part per million per degree Celsius of the second CTE.

Example 3 includes the subject matter of any of Examples 1 and 2, and wherein the first CTE is 2-4 parts per million per degree Celsius, wherein the second CTE is 2-4 parts per million per degree Celsius.

Example 4 includes the subject matter of any of Examples 1-3, and wherein the one or more dies comprise a plurality of dies, wherein the plurality of dies have a die-to-die spacing less than 50 micrometers.

Example 5 includes the subject matter of any of Examples 1-4, and wherein the one or more build-up layers comprise a first set of build-up layers and a second set of build-up layers, wherein the first set of build-up layers is adjacent the bottom side, wherein the second set of build-up layers is adjacent the first set of build-up layers, wherein the first set of build-up layers has a minimum trace size of less than 3 micrometers, wherein the second set of build-up layers has a minimum trace size greater than 7 micrometers.

Example 6 includes the subject matter of any of Examples 1-5, and further including a bridge die disposed in the glass core, wherein the bridge die is adjacent the one or more dies.

Example 7 includes the subject matter of any of Examples 1-6, and wherein the bridge die has a minimum trace size of less than 0.5 micrometers.

Example 8 includes the subject matter of any of Examples 1-7, and wherein the glass core comprises a first sub-core and a second sub-core, wherein the first sub-core comprises the top side, wherein the second sub-core comprises the bottom side, wherein the first sub-core has a first coefficient of thermal expansion (CTE), wherein the second sub-core has a second CTE, the second CTE different from the first CTE.

Example 9 includes the subject matter of any of Examples 1-8, and further including a die adjacent the top side of the glass core, wherein the die has a third CTE, wherein the first CTE is within 20% of the third CTE.

Example 10 includes the subject matter of any of Examples 1-9, and wherein the one or more build-up layers has a fourth CTE, wherein the second CTE is within 20% of the fourth CTE.

Example 11 includes the subject matter of any of Examples 1-10, and wherein the fourth CTE is at least twice that of the third CTE.

Example 12 includes the subject matter of any of Examples 1-11, and wherein, at an interface between the first sub-core and an adjacent sub-core, there is increased oxygen concentration relative to nearby areas.

Example 13 includes the subject matter of any of Examples 1-12, and wherein the glass core further comprises a third sub-core, wherein the third sub-core is between the first sub-core and the second sub-core, wherein the third sub-core is adjacent the first sub-core and adjacent the second sub-core.

Example 14 includes the subject matter of any of Examples 1-13, and wherein the third sub-core as a coefficient of thermal expansion (CTE) between that of the first sub-core and the second sub-core.

Example 15 includes the subject matter of any of Examples 1-14, and further including a thin-film bridge die disposed in the glass core, wherein the thin-film bridge die does not have a substrate besides the glass core.

Example 16 includes the subject matter of any of Examples 1-15, and wherein the thin-film bridge die is adhered to the glass core by an adhesive.

Example 17 includes the subject matter of any of Examples 1-16, and wherein the thin-film bridge die has a thickness less than 20 micrometers.

Example 18 includes the subject matter of any of Examples 1-17, and wherein the thin-film bridge die comprises a metal-insulator-metal (MIM) capacitor.

Example 19 includes an apparatus comprising a glass core, the glass core comprising a top side and a bottom side, the glass core comprising a first sub-core and a second sub-core, the first sub-core comprising the top side, the second sub-core comprising the bottom side; and one or more build-up layers adjacent the bottom side.

Example 20 includes the subject matter of Example 19, and wherein the first sub-core has a first coefficient of thermal expansion (CTE), wherein the second sub-core has a second CTE, the second CTE different from the first CTE.

Example 21 includes the subject matter of any of Examples 19 and 20, and further including a die adjacent the top side of the glass core, wherein the die has a third CTE, wherein the first CTE is within 20% of the third CTE.

Example 22 includes the subject matter of any of Examples 19-21, and wherein the one or more build-up layers has a fourth CTE, wherein the second CTE is within 20% of the fourth CTE.

Example 23 includes the subject matter of any of Examples 19-22, and wherein the fourth CTE is at least twice that of the third CTE.

Example 24 includes the subject matter of any of Examples 19-23, and wherein, at an interface between the first sub-core and an adjacent sub-core, there is increased oxygen concentration relative to nearby areas.

Example 25 includes the subject matter of any of Examples 19-24, and wherein the glass core further comprises a third sub-core, wherein the third sub-core is between the first sub-core and the second sub-core, wherein the third sub-core is adjacent the first sub-core and adjacent the second sub-core.

Example 26 includes the subject matter of any of Examples 19-25, and wherein the third sub-core as a coefficient of thermal expansion (CTE) between that of the first sub-core and the second sub-core.

Example 27 includes the subject matter of any of Examples 19-26, and further including one or more dies adjacent the top side, wherein the glass core has a first coefficient of thermal expansion (CTE), wherein the one or more dies have a second CTE, wherein the first CTE is within 1 part per million per degree Celsius of the second CTE.

Example 28 includes the subject matter of any of Examples 19-27, and wherein the first CTE is 2-4 parts per million per degree Celsius, wherein the second CTE is 2-4 parts per million per degree Celsius.

Example 29 includes the subject matter of any of Examples 19-28, and further including one or more dies adjacent the top side, wherein the one or more dies comprise a plurality of dies, wherein the plurality of dies have a die-to-die spacing less than 50 micrometers.

Example 30 includes the subject matter of any of Examples 19-29, and wherein the one or more build-up layers comprise a first set of build-up layers and a second set of build-up layers, wherein the first set of build-up layers is adjacent the bottom side, wherein the second set of build-up layers is adjacent the first set of build-up layers, wherein the first set of build-up layers has a minimum trace size of less than 3 micrometers, wherein the second set of build-up layers has a minimum trace size greater than 7 micrometers.

Example 31 includes the subject matter of any of Examples 19-30, and further including a bridge die disposed in the glass core; and one or more dies adjacent the top side, wherein the bridge die is adjacent the one or more dies.

Example 32 includes the subject matter of any of Examples 19-31, and wherein the bridge die has a minimum trace size of less than 0.5 micrometers.

Example 33 includes the subject matter of any of Examples 19-32, and further including a thin-film bridge die disposed in the glass core, wherein the thin-film bridge die does not have a substrate besides the glass core.

Example 34 includes the subject matter of any of Examples 19-33, and wherein the thin-film bridge die is adhered to the glass core by an adhesive.

Example 35 includes the subject matter of any of Examples 19-34, and wherein the thin-film bridge die has a thickness less than 20 micrometers.

Example 36 includes the subject matter of any of Examples 19-35, and wherein the thin-film bridge die comprises a metal-insulator-metal (MIM) capacitor.

Example 37 includes an apparatus comprising a glass core, the glass core comprising a top side and a bottom side; a thin-film bridge die positioned in the glass core; and one or more dies adjacent the top side of the glass core, wherein the thin-film bridge die is adjacent the one or more dies.

Example 38 includes the subject matter of Example 37, and wherein the thin-film bridge die does not have a substrate besides the glass core.

Example 39 includes the subject matter of any of Examples 37 and 38, and wherein the thin-film bridge die is adhered to the glass core by an adhesive.

Example 40 includes the subject matter of any of Examples 37-39, and wherein the thin-film bridge die has a thickness less than 20 micrometers.

Example 41 includes the subject matter of any of Examples 37-40, and wherein the thin-film bridge die comprises a metal-insulator-metal (MIM) capacitor.

Example 42 includes the subject matter of any of Examples 37-41, and wherein the glass core has a first coefficient of thermal expansion (CTE), wherein the one or more dies have a second CTE, wherein the first CTE is within 1 part per million per degree Celsius of the second CTE.

Example 43 includes the subject matter of any of Examples 37-42, and wherein the first CTE is 2-4 parts per million per degree Celsius, wherein the second CTE is 2-4 parts per million per degree Celsius.

Example 44 includes the subject matter of any of Examples 37-43, and wherein the one or more dies comprise a plurality of dies, wherein the plurality of dies have a die-to-die spacing less than 50 micrometers.

Example 45 includes the subject matter of any of Examples 37-44, and further including one or more build-up layers adjacent the bottom side, wherein the one or more build-up layers comprise a first set of build-up layers and a second set of build-up layers, wherein the first set of build-up layers is adjacent the bottom side, wherein the second set of build-up layers is adjacent the first set of build-up layers, wherein the first set of build-up layers has a minimum trace size of less than 3 micrometers, wherein the second set of build-up layers has a minimum trace size greater than 7 micrometers.

Example 46 includes the subject matter of any of Examples 37-45, and further including a bridge die disposed in the glass core, wherein the bridge die is adjacent the one or more dies.

Example 47 includes the subject matter of any of Examples 37-46, and wherein the bridge die has a minimum trace size of less than 0.5 micrometers.

Example 48 includes the subject matter of any of Examples 37-47, and wherein the glass core comprises a first sub-core and a second sub-core, wherein the first sub-core comprises the top side, wherein the second sub-core comprises the bottom side, wherein the first sub-core has a first coefficient of thermal expansion (CTE), wherein the second sub-core has a second CTE, the second CTE different from the first CTE.

Example 49 includes the subject matter of any of Examples 37-48, and further including a die adjacent the top side of the glass core, wherein the die has a third CTE, wherein the first CTE is within 20% of the third CTE.

Example 50 includes the subject matter of any of Examples 37-49, and further including one or more build-up layers adjacent the bottom side, wherein the one or more build-up layers has a fourth CTE, wherein the second CTE is within 20% of the fourth CTE.

Example 51 includes the subject matter of any of Examples 37-50, and wherein the fourth CTE is at least twice that of the third CTE.

Example 52 includes the subject matter of any of Examples 37-51, and wherein, at an interface between the first sub-core and an adjacent sub-core, there is increased oxygen concentration relative to nearby areas.

Example 53 includes the subject matter of any of Examples 37-52, and wherein the glass core further comprises a third sub-core, wherein the third sub-core is between the first sub-core and the second sub-core, wherein the third sub-core is adjacent the first sub-core and adjacent the second sub-core.

Example 54 includes the subject matter of any of Examples 37-53, and wherein the third sub-core as a coefficient of thermal expansion (CTE) between that of the first sub-core and the second sub-core.

1. An apparatus comprising:
a glass core, the glass core comprising a top side and a bottom side;
one or more dies adjacent the top side of the glass core; and
one or more build-up layers adjacent the bottom side.

2. The apparatus of claim 1, wherein the glass core has a first coefficient of thermal expansion (CTE), wherein the one or more dies have a second CTE, wherein the first CTE is within 1 part per million per degree Celsius of the second CTE.

3. The apparatus of claim 2, wherein the first CTE is 2-4 parts per million per degree Celsius, wherein the second CTE is 2-4 parts per million per degree Celsius.

4. The apparatus of claim 1, wherein the one or more dies comprise a plurality of dies, wherein the plurality of dies have a die-to-die spacing less than 50 micrometers.

5. The apparatus of claim 1, wherein the one or more build-up layers comprise a first set of build-up layers and a second set of build-up layers,
wherein the first set of build-up layers is adjacent the bottom side, wherein the second set of build-up layers is adjacent the first set of build-up layers,
wherein the first set of build-up layers has a minimum trace size of less than 3 micrometers, wherein the second set of build-up layers has a minimum trace size greater than 7 micrometers.

6. The apparatus of claim 1, further comprising a bridge die disposed in the glass core, wherein the bridge die is adjacent the one or more dies.

7. The apparatus of claim 6, wherein the bridge die has a minimum trace size of less than 0.5 micrometers.

8. An apparatus comprising:
a glass core, the glass core comprising a top side and a bottom side, the glass core comprising a first sub-core and a second sub-core, the first sub-core comprising the top side, the second sub-core comprising the bottom side; and
one or more build-up layers adjacent the bottom side.

9. The apparatus of claim 8, wherein the first sub-core has a first coefficient of thermal expansion (CTE), wherein the second sub-core has a second CTE, the second CTE different from the first CTE.

10. The apparatus of claim 9, further comprising a die adjacent the top side of the glass core, wherein the die has a third CTE, wherein the first CTE is within 20% of the third CTE.

11. The apparatus of claim 10, wherein the one or more build-up layers has a fourth CTE, wherein the second CTE is within 20% of the fourth CTE.

12. The apparatus of claim 11, wherein the fourth CTE is at least twice that of the third CTE.

13. The apparatus of claim 8, wherein, at an interface between the first sub-core and an adjacent sub-core, there is increased oxygen concentration relative to nearby areas.

14. The apparatus of claim 8, wherein the glass core further comprises a third sub-core, wherein the third sub-core is between the first sub-core and the second sub-core, wherein the third sub-core is adjacent the first sub-core and adjacent the second sub-core.

15. The apparatus of claim 14, wherein the third sub-core as a coefficient of thermal expansion (CTE) between that of the first sub-core and the second sub-core.

16. An apparatus comprising:
a glass core, the glass core comprising a top side and a bottom side;
a thin-film bridge die positioned in the glass core; and
one or more dies adjacent the top side of the glass core, wherein the thin-film bridge die is adjacent the one or more dies.

17. The apparatus of claim 16, wherein the thin-film bridge die does not have a substrate besides the glass core.

18. The apparatus of claim 17, wherein the thin-film bridge die is adhered to the glass core by an adhesive.

19. The apparatus of claim 16, wherein the thin-film bridge die has a thickness less than 20 micrometers.

20. The apparatus of claim 16, wherein the thin-film bridge die comprises a metal-insulator-metal (MIM) capacitor.
